(19) United States
(12) Patent Application Publication
(10) Pub. No.: US 2025/0176375 A1
(43) Pub. Date: May 29, 2025

(54) DISPLAY PANEL AND DISPLAY DEVICE

(71) Applicants: Chengdu BOE Optoelectronics Technology, Co., Ltd., Sichuan (CN); BOE TECHNOLOGY GROUP CO., LTD., Beijing (CN)

(72) Inventors: Tiaomei ZHANG, Beijing (CN); Ziyang YU, Beijing (CN); Yujing Li, Beijing (CN); Zhiliang JIANG, Beijing (CN); Ming HU, Beijing (CN); Haijun Qiu, Beijing (CN)

(21) Appl. No.: 18/842,819

(22) PCT Filed: Dec. 2, 2022
(86) PCT No.: PCT/CN2022/136318

§ 371 Date: Aug. 30, 2024

(51) Int. Cl. H10K 59/126; H10K 59/121; H10K 59/122; H10K 59/131; H10K 102/00

(52) U.S. Cl. CPC H10K 59/126; H10K 59/1213; H10K 59/122; H10K 59/131; H10K 2102/361

(57) ABSTRACT

A display panel includes: a light emitting unit; a base substrate, including a light transmitting area; a light shielding layer, located on a side of the base substrate and configured with a light shielding function; a pixel defining layer, located on a side of the light shielding layer away from the base substrate, wherein a pixel opening is formed on the pixel defining layer, and the light emitting unit is formed in the pixel opening; and multiple functional layers, located between the base substrate and the pixel defining layer, and orthographic projections, on the base substrate, of light shielding structures of the multiple functional layers are located outside the light transmitting area; wherein a first opening is formed on the light shielding layer, and an orthographic projection of the first opening on the base substrate is located in the light transmitting area.

### TECHNICAL FIELD

This disclosure relates to the field of display technology, and in particular to a display panel and a display device.

### BACKGROUND

In a display panel with a high pixel density, the light transmittance of the display panel is relatively low, so that the display panel cannot meet the light transmittance requirements of technologies such as fingerprint recognition and under-screen cameras.

It is to be noted that the above information disclosed in this background section is only for enhancing understanding the context of the disclosure and, therefore, may contain information that does not form the prior art that is already known to those skilled in the art.

### SUMMARY

According to an aspect of this disclosure, a display panel is provided and includes: a light emitting unit. The display panel further includes: a base substrate, a light shielding layer, a pixel defining layer and multiple functional layers. The base substrate includes a light transmitting area. The light shielding layer is located on a side of the base substrate and configured with a light shielding function. The pixel defining layer is located on a side of the light shielding layer away from the base substrate, where a pixel opening is formed on the pixel defining layer, and the light emitting unit is formed in the pixel opening. The multiple functional layers are located between the base substrate and the pixel defining layer, and orthographic projections, on the base substrate, of light shielding structures of all the functional layers between the base substrate and the pixel defining layer are located outside the light transmitting area. A first opening is formed on the light shielding layer, and an orthographic projection of the first opening on the base substrate is located in the light transmitting area.

In an exemplary embodiment of this disclosure, the display panel further includes a pixel driving circuit for driving the light emitting unit, where the pixel driving circuit includes a driving transistor. The multiple functional layers include: a first active layer, including a third active part, where the third active part is configured to form a channel region of the driving transistor. The light shielding layer is located between the first active layer and the base substrate, the light shielding layer includes a first light shielding part, and an orthographic projection of the first light shielding part on the base substrate covers an orthographic projection of the third active part on the base substrate.

In an exemplary embodiment of this disclosure, the pixel driving circuit further includes a first transistor and a fourth transistor, a first electrode of the first transistor is connected to a first initial signal line, a second electrode of the first transistor is connected to a gate of the driving transistor, a first electrode of the fourth transistor is connected to a data line, and a second electrode of the fourth transistor is connected to a first electrode of the driving transistor. The display panel further includes: a first reset signal line and a second gate line. An orthographic projection of the first reset signal line on the base substrate extends along a first direction, and a partial structure of the first reset signal line is configured to form a top gate of the first transistor. An orthographic projection of the second gate line on the base substrate extends along the first direction, and a partial structure of the second gate line is configured to form a gate of the fourth transistor. The orthographic projection of the first opening on the base substrate is located between the orthographic projections, on the base substrate, of the first reset signal line and the second gate line in the same pixel driving circuit.

In an exemplary embodiment of this disclosure, the display panel includes a plurality of repeating units, where the repeating units are arranged in an array in a first direction and a second direction, and the first direction intersects with the second direction. The repeating unit includes two pixel driving circuits arranged in the first direction, and the two pixel driving circuits in the same repeating unit are arranged in mirror symmetry.

In an exemplary embodiment of this disclosure, the pixel driving circuit further includes a fourth transistor, a first electrode of the fourth transistor is connected to a data line, and a second electrode of the fourth transistor is connected to a first electrode of the driving transistor. An orthographic projection of the data line on the base substrate extends along the second direction, and the orthographic projection of the first opening on the base substrate is located between orthographic projections, on the base substrate, of two adjacent data lines in the same repeating unit.

In an exemplary embodiment of this disclosure, the pixel driving circuit further includes a sixth transistor and a seventh transistor, a first electrode of the sixth transistor is connected to a second electrode of the driving transistor, a second electrode of the sixth transistor is connected to a first electrode of the light emitting unit, a first electrode of the seventh transistor is connected to a second initial signal line, and a second electrode of the seventh transistor is connected to the first electrode of the light emitting unit. The first active layer further includes: a sixth active part, a seventh active part and an eighth active part. The sixth active part is configured to form a channel region of the sixth transistor. The seventh active part is configured to form a channel region of the seventh transistor. The eighth active part is connected between the sixth active part and the seventh active part. The light shielding layer further includes: a second light shielding part, connected to the first light shielding part, where an orthographic projection of the eighth active part on the base substrate at least partially overlaps with an orthographic projection of the second light shielding part on the base substrate.

In an exemplary embodiment of this disclosure, the orthographic projection of the eighth active part on the base substrate extends along a first direction, and a size, in the first direction, of the orthographic projection of the eighth active part on the base substrate is greater than a size, in a second direction, of the orthographic projection of the eighth active part on the base substrate; and the orthographic projection of the second light shielding part on the base substrate extends along the first direction, and a size, in the first direction, of the orthographic projection of the second light shielding part on the base substrate is greater than a size, in the second direction, of the orthographic projection of the second light shielding part on the base substrate; where the first direction intersects with the second direction.

In an exemplary embodiment of this disclosure, the light shielding layer further includes a third light shielding part. An orthographic projection of the third light shielding part on the base substrate extends along the second direction, and the third light shielding part is connected between the first light shielding part and the second light shielding part. The second light shielding part includes a first light shielding subpart and a second light shielding subpart. In the first direction, orthographic projections of the first light shielding subpart and the second light shielding subpart on the base substrate are located on both sides of an orthographic projection of the third light shielding part on the base substrate. The orthographic projection of the first light shielding subpart on the base substrate at least partially overlaps with the orthographic projection of the eighth active part on the base substrate, and the orthographic projection of the second light shielding subpart on the base substrate at least partially overlaps with the orthographic projection of the eighth active part on the base substrate. The first active layer further includes a ninth active part, where an orthographic projection of the ninth active part on the base substrate extends along the second direction, and the ninth active part is connected between the eighth active part and the seventh active part. The eighth active part includes a first active subpart and a second active subpart. In the first direction, orthographic projections of the first active subpart and the second active subpart on the base substrate are located on both sides of an orthographic projection of the ninth active part on the base substrate. The orthographic projection of the first active subpart on the base substrate at least partially overlaps with the orthographic projection of the second light shielding part on the base substrate, and the orthographic projection of the second active subpart on the base substrate at least partially overlaps with the orthographic projection of the second light shielding part on the base substrate.

In an exemplary embodiment of this disclosure, the display panel includes a plurality of repeating units, where the repeating units are arranged in an array in a first direction and a second direction, and the first direction intersects with the second direction. The repeating unit includes two pixel driving circuits arranged in the first direction, and the two pixel driving circuits in the same repeating unit are arranged in mirror symmetry. The first light shielding layer further includes: a fourth light shielding part, provided corresponding to the repeating unit, where the fourth light shielding part is connected to two second light shielding parts in the corresponding repeating unit. The fourth light shielding part is connected to an end of the second light shielding part away from the first light shielding part, and the first opening is formed on the fourth light shielding part.

In an exemplary embodiment of this disclosure, the pixel driving circuit further includes a second transistor, a first electrode of the second transistor is connected to a gate of the driving transistor, and a second electrode of the second transistor is connected to the second electrode of the driving transistor. The multiple functional layers further include: a first conductive layer and a fourth conductive layer. The first conductive layer is located between the first active layer and the pixel defining layer, where the first conductive layer includes a first conductive part, an orthographic projection of the first conductive part on the base substrate covers the orthographic projection of the third active part on the base substrate, and the first conductive part is configured to form the gate of the driving transistor. The fourth conductive layer is located between the first conductive layer and the pixel defining layer, where the fourth conductive layer includes a first bridge part and a second bridge part. The first bridge part is connected to the first electrode of the second transistor, and the first bridge part is connected to the first conductive part through a via. The second bridge part is connected to the eighth active part through a via, and a size, in a first direction, of an orthographic projection of the second bridge part on the base substrate is greater than a size, in a second direction, of the orthographic projection of the second bridge part on the base substrate.

In an exemplary embodiment of this disclosure, an area of the orthographic projection of the first opening on the base substrate is smaller than an area of the orthographic projection of the first light shielding part on the base substrate.

In an exemplary embodiment of this disclosure, the pixel driving circuit further includes a first transistor and a second transistor, where a first electrode of the first transistor is connected to a first initial signal line, a second electrode of the first transistor is connected to a gate of the driving transistor, a first electrode of the second transistor is connected to the gate of the driving transistor, and a second electrode of the second transistor is connected to a second electrode of the driving transistor. The multiple functional layers further include: a first conductive layer and a fourth conductive layer. The first conductive layer is located between the first active layer and the pixel defining layer, where the first conductive layer includes a first conductive part, an orthographic projection of the first conductive part on the base substrate covers the orthographic projection of the third active part on the base substrate, and the first conductive part is configured to form the gate of the driving transistor. The fourth conductive layer is located between the first conductive layer and the pixel defining layer, where the fourth conductive layer includes a first bridge part and the first initial signal line, and an orthographic projection of the first initial signal line on the base substrate extends along a first direction. The first bridge part is connected to the first electrode of the second transistor, and the first bridge part is connected to the first conductive part through a via.

In an exemplary embodiment of this disclosure, the pixel driving circuit further includes a capacitor, where a first electrode of the capacitor is connected to a gate of the driving transistor, and a second electrode of the capacitor is connected to a first power line. The multiple functional layers further include: a first conductive layer, a second conductive layer, a fourth conductive layer and a fifth conductive layer. The first conductive layer is located between the first active layer and the pixel defining layer, where the first conductive layer includes a first conductive part, an orthographic projection of the first conductive part on the base substrate covers the orthographic projection of the third active part on the base substrate, and the first conductive part is configured to form the gate of the driving transistor and the first electrode of the capacitor. The second conductive layer is located between the first conductive layer and the pixel defining layer, where the second conductive layer includes a second conductive part and a first connecting part, an orthographic projection of the second conductive part on the base substrate at least partially overlaps with the orthographic projection of the first conductive part on the base substrate, the second conductive part is configured to form the second electrode of the capacitor, and the first connecting part is connected between two second conductive parts in the same repeating unit. The fourth conductive layer is located between the second conductive layer and the pixel defining layer, where the fourth conductive layer includes a first power connection line, an orthographic projection of the first power connection line on the base substrate extends along the first direction, and the first power connection line is connected to the first connecting part through a via. The fifth conductive layer is located on a side of the fourth conductive layer away from the base substrate, where the fifth conductive layer includes the first power line; and in two repeating units adjacent in the first direction, two adjacent first power lines are connected, and the two connected first power lines are connected to the first power connection line through a via.

In an exemplary embodiment of this disclosure, the pixel defining layer is black, a second opening is further formed on the pixel defining layer, and an orthographic projection of the second opening on the base substrate is located in the light transmitting area. The orthographic projection of the second opening on the base substrate coincides with the orthographic projection of the first opening on the base substrate. Alternatively, an area of the orthographic projection of the second opening on the base substrate is greater than an area of the orthographic projection of the first opening on the base substrate, and the orthographic projection of the second opening on the base substrate covers the orthographic projection of the first opening on the base substrate. Alternatively, an area of the orthographic projection of the first opening on the base substrate is greater than an area of the orthographic projection of the second opening on the base substrate, and the orthographic projection of the first opening on the base substrate covers the orthographic projection of the second opening on the base substrate.

In an exemplary embodiment of this disclosure, the display panel includes a display area, where the display area includes an optical signal collection area, and the first opening is formed on at least the light shielding layer in the optical signal collection area.

In an exemplary embodiment of this disclosure, the display area further includes a normal display area outside the optical signal collection area. An orthographic projection, on the base substrate, of the light shielding layer located in the optical signal collection area and an orthographic projection, on the base substrate, of the light shielding layer located in the normal display area have different pattern shapes.

In an exemplary embodiment of this disclosure, the display area further includes a normal display area outside the optical signal collection area, and the first opening is further formed on the light shielding layer in the normal display area. An orthographic projection, on the base substrate, of the light shielding layer located in the optical signal collection area and an orthographic projection, on the base substrate, of the light shielding layer located in the normal display area have a same pattern shape.

In an exemplary embodiment of this disclosure, the light shielding layer located in the optical signal collection area is provided as an entire surface except for the first opening.

In an exemplary embodiment of this disclosure, the pixel driving circuit further includes a plurality of switching transistors. The first active layer further includes: a plurality of active parts, configured to form channel regions of the switch transistors. A plurality of first openings are further formed on the light shielding layer located in the optical signal collection area, the first openings are provided corresponding to the active parts, and orthographic projections of the first openings on the base substrate cover orthographic projections of corresponding active parts on the base substrate.

In an exemplary embodiment of this disclosure, the light shielding layer located in the normal display area further includes a plurality of second connecting parts and a plurality of third connecting parts. The second connecting parts have their orthographic projections on the base substrate extending along a first direction, and are connected between the first light shielding parts adjacent in the first direction. The third connecting parts have their orthographic projections on the base substrate extending along a second direction, and are connected between the first light shielding parts adjacent in the second direction, where the first direction intersects with the second direction.

In an exemplary embodiment of this disclosure, the display panel further includes a display area, where the display area includes a fan-out area and an optical signal collection area. The display panel further includes: a plurality of data lines, a plurality of first data fan-out lines and a plurality of second data fan-out lines. The plurality of data lines are located in the display area, where orthographic projections of the data lines on the base substrate are spaced apart along a first direction and extend along a second direction, and the first direction intersects with the second direction. The plurality of first data fan-out lines are located in the fan-out area, where orthographic projections of the first data fan-out lines on the base substrate are spaced apart along the second direction and extend along the first direction, the first data fan-out lines are provided corresponding to the data lines, and the first data fan-out lines are respectively connected to the corresponding data lines. The plurality of second data fan-out lines are located in the fan-out area, where orthographic projections of the second data fan-out lines on the base substrate are spaced apart along the first direction and extend along the second direction, the second data fan-out lines are provided corresponding to the first data fan-out lines, and the second data fan-out lines are respectively connected to the corresponding first data fan-out lines. The first data fan-out lines are located in the light shielding layer.

In an exemplary embodiment of this disclosure, the multiple functional layers further include: a fifth conductive layer, located between the base substrate and the pixel defining layer, where the fifth conductive layer includes the data lines. The light shielding layer is located between the fifth conductive layer and the pixel defining layer.

In an exemplary embodiment of this disclosure, the display area further includes a remaining display area outside the fan-out area and the optical signal collection area. The display panel further includes: a plurality of first signal lines, located in a conductive layer outside the light shielding layer. The light shielding layer located in the remaining display area includes multiple second signal lines, orthographic projections of the first signal lines on the base substrate intersects with orthographic projections of the second signal lines on the base substrate, and the second signal lines are respectively connected to the intersecting first signal lines through a via.

In an exemplary embodiment of this disclosure, the display panel further includes a pixel driving circuit, which includes a driving transistor, a first transistor, a fifth transistor, and a seventh transistor. A first electrode of the first transistor is connected to a first initial signal line, and a second electrode of the first transistor is connected to a gate of the driving transistor. A first electrode of the fifth transistor is connected to a first power line, and a second electrode of the fifth transistor is connected to a first electrode of the driving transistor. A first electrode of the seventh transistor is connected to a second initial signal line, and a second electrode of the seventh transistor is connected to a first electrode of the light emitting unit. The plurality of first signal lines include one or more of the first initial signal line, the second initial signal line, and the first power line.

In an exemplary embodiment of this disclosure, the display area further includes a remaining display area located outside the fan-out area and the optical signal collection area. The display panel further includes a common electrode layer. The common electrode layer is located on a side of the pixel defining layer away from the base substrate, and the common electrode layer is configured to form the second electrode of the light emitting unit. The light shielding layer located in the remaining display area includes a plurality of second power lines connected to the common electrode layer.

In an exemplary embodiment of this disclosure, orthographic projections of some of the second power lines on the base substrate extend along the first direction, and orthographic projections of some of the second power lines on the base substrate extend along the second direction, and the second power lines with different extension directions intersect.

In an exemplary embodiment of this disclosure, the display panel further includes a pixel driving circuit configured to drive the light emitting unit to emit light. The pixel driving circuit includes: a driving transistor, a first transistor, a second transistor, a fourth transistor, a fifth transistor, a sixth transistor, a seventh transistor, and a capacitor. A first electrode of the first transistor is connected to a first initial signal line, and a second electrode thereof is connected to a gate of the driving transistor. A first electrode of the second transistor is connected to the gate of the driving transistor, and a second electrode thereof is connected to a second electrode of the driving transistor. A first electrode of the fourth transistor is connected to the data line, and a second electrode thereof is connected to a first electrode of the driving transistor. A first electrode of the fifth transistor is connected to a first power line, and a second electrode thereof is connected to the first electrode of the driving transistor. A first electrode of the sixth transistor is connected to the second electrode of the driving transistor, and a second electrode thereof is connected to the first electrode of the light emitting unit. A first electrode of the seventh transistor is connected to a second initial signal line, and a second electrode thereof is connected to the first electrode of the light emitting unit. A first electrode of the capacitor is connected to the gate of the driving transistor, and a second electrode thereof is connected to the first power line. The first transistor and the second transistor are N-type transistors, and the driving transistor, the fourth transistor, the fifth transistor, the sixth transistor, and the seventh transistor are P-type transistors.

In an exemplary embodiment of this disclosure, the multiple functional layers include: a first active layer, a first conductive layer, a second active layer, and a third conductive layer. The first active layer is located between the base substrate and the pixel defining layer, and the first active layer includes: a third active part, a fourth active part, a fifth active part, a sixth active part, and a seventh active part. The third active part is configured to form a channel region of the driving transistor, the fourth active part is configured to form a channel region of the fourth transistor, the fifth active part is configured to form a channel region of the fifth transistor, the sixth active part is configured to form a channel region of the sixth transistor, and the seventh active part is configured to form a channel region of the seventh transistor. The first conductive layer is located between the first active layer and the pixel defining layer, and the first conductive layer includes: a second reset signal line, a second gate line, an enable signal line, and a first conductive part. Orthographic projections of the second reset signal line, the second gate line, and the enable signal line on the base substrate extend along the first direction. The first conductive part is configured to form the gate of the driving transistor and the first electrode of the capacitor. A partial structure of the second gate line is configured to form a gate of the fourth transistor, a partial structure of the second reset signal line is configured to form a gate of the seventh transistor, and a partial structure of the enable signal line is configured to form gate of the fifth transistor and the sixth transistor respectively. The second active layer is located between the first conductive layer and the pixel defining layer, and the second active layer includes a first active part and a second active part. The first active part is configured to form a channel region of the first transistor, and the second active part is configured to form a channel region of the second transistor. The third conductive layer is located between the second active layer and the pixel defining layer, and the third conductive layer includes: the first gate line and the first reset signal line, where orthographic projections of the first gate line and the first reset signal line on the base substrate extend along the first direction. A partial structure of the first gate line is configured to form a top gate of the second transistor, and a partial structure of the first reset signal line is configured to form a top gate of the first transistor.

In an exemplary embodiment of this disclosure, in the same pixel driving circuit, orthographic projections of the first reset signal line, the second gate line, the first gate line, the first conductive part, the enable signal line, and the second reset signal line on the base substrate are sequentially arranged in the second direction, where the first direction intersects with the second direction. The second gate line in a pixel driving circuit of a current row is reused as the second reset signal line in a pixel driving circuit of a previous row.

In an exemplary embodiment of this disclosure, the display panel further includes a pixel driving circuit, which is configured to drive the light emitting unit to emit light. The multiple functional layers further include: an electrode layer, where the electrode layer includes a plurality of electrode parts, and the electrode parts are configured to form the first electrode of the light-emitting unit. The plurality of electrode parts include a first electrode part, a second electrode part, and a third electrode part. In the plurality of electrode parts connected to pixel driving circuits in the same row, the second electrode part, the first electrode part, the third electrode part, and the first electrode part are alternately arranged in sequence in the row direction. In two adjacent columns of pixel driving circuits, a plurality of second electrode parts and a plurality of third electrode parts are connected to pixel driving circuits in the same column, and the second electrode parts and the third electrode parts connected to the pixel driving circuits in the same column are alternately arranged in sequence in the column direction; a plurality of first electrode parts are connected to the pixel driving circuit in another column, and the first electrode parts connected to the pixel driving circuit in the same column are spaced apart in the column direction.

In an exemplary embodiment of this disclosure, the first opening is configured to project, through pinhole imaging, an optical signal on one side of the display panel onto another side of the display panel.

According to an aspect of this disclosure, a display panel is provided and includes a base substrate, a light shielding layer and multiple functional layers. The light shielding layer is located on a side of the base substrate and configured with a light shielding function. The multiple functional layers are located on a side of the base substrate. A first opening is formed on the light shielding layer, where an orthographic projection of the first opening on the base substrate does not overlap with orthographic projections, on the base substrate, of light shielding structures in the functional layers, and an orthographic projection of the light shielding layer on the base substrate overlaps with an orthographic projection, on the base substrate, of a light shielding structure in at least one of the functional layers.

In an exemplary embodiment of this disclosure, the display panel further includes a light emitting unit and a pixel driving circuit for driving the light emitting unit, where the pixel driving circuit includes a driving transistor. The multiple functional layers include: a first active layer, including a third active part, where the third active part is configured to form a channel region of the driving transistor. The light shielding layer is located between the first active layer and the base substrate, and the light shielding layer includes a first light shielding part, where an orthographic projection of the first light shielding part on the base substrate covers an orthographic projection of the third active part on the base substrate. The pixel driving circuit further includes a first transistor and a fourth transistor, where a first electrode of the first transistor is connected to a first initial signal line, and a second electrode of the first transistor is connected to a gate of the driving transistor; a first electrode of the fourth transistor is connected to a data line, and a second electrode of the fourth transistor is connected to a first electrode of the driving transistor. The display panel further includes: a first reset signal line and a second gate line. An orthographic projection of the first reset signal line on the base substrate extends along a first direction, and a partial structure of the first reset signal line is configured to form a top gate of the first transistor. An orthographic projection of the second gate line on the base substrate extends along the first direction, and a partial structure of the second gate line is configured to form a gate of the fourth transistor. The orthographic projection of the first opening on the base substrate is located between the orthographic projections, on the base substrate, of the first reset signal line and the second gate line in the same pixel driving circuit.

In an exemplary embodiment of this disclosure, the display panel includes a display area, where the display area includes a fan-out area and an optical signal collection area. The display panel further includes: a plurality of data lines, a plurality of first data fan-out lines and a plurality of second data fan-out lines. The plurality of data lines are located in the display area, where orthographic projections of the data lines on the base substrate are spaced apart along a first direction and extend along a second direction, and the first direction intersects with the second direction. The plurality of first data fan-out lines are located in the fan-out area, where orthographic projections of the first data fan-out lines on the base substrate are spaced apart along the second direction and extend along the first direction, the first data fan-out lines are provided corresponding to the data lines, and the first data fan-out lines are respectively connected to the corresponding data lines. The plurality of second data fan-out lines are located in the fan-out area, where orthographic projections of the second data fan-out lines on the base substrate are spaced apart along the first direction and extend along the second direction, the second data fan-out lines are provided corresponding to the first data fan-out lines, and the second data fan-out lines are respectively connected to the corresponding first data fan-out lines. The first data fan-out lines are located in the light shielding layer.

According to an aspect of this disclosure, a display device is provided and includes the forgoing display panel.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a schematic diagram of a circuit structure of a pixel driving circuit in the related art.

FIG. 2 is a timing diagram of respective nodes in a driving method of the pixel driving circuit in FIG. 1.

FIG. 3 is a structural layout diagram of a display panel according to an exemplary embodiment of this disclosure.

FIG. 4 is a structural layout diagram of the light shielding layer in FIG. 3.

FIG. 5 is a structural layout diagram of the first active layer in FIG. 3.

FIG. 6 is a structural layout diagram of the first conductive layer in FIG. 3.

FIG. 7 is a structural layout diagram of the second conductive layer in FIG. 3.

FIG. 8 is a structural layout diagram of the second active layer in FIG. 3.

FIG. 9 is a structural layout diagram of the third conductive layer in FIG. 3.

FIG. 10 is a structural layout diagram of the fourth conductive layer in FIG. 3.

FIG. 11 is a structural layout diagram of the fifth conductive layer in FIG. 3.

FIG. 12 is a structural layout diagram of the electrode layer and the pixel defining layer in FIG. 3.

FIG. 13 is a structural layout diagram of the pixel defining layer in FIG. 3.

FIG. 14 is a structural layout diagram of the light shielding layer and the first active layer in FIG. 3.

FIG. 15 is a structural layout diagram of the light shielding layer, the first active layer, and the first conductive layer in FIG. 3.

FIG. 16 is a structural layout diagram of the light shielding layer, the first active layer, the first conductive layer, and the second conductive layer in FIG. 3.

FIG. 17 is a structural layout diagram of the light shielding layer, the first active layer, the first conductive layer, the second conductive layer, and the second active layer in FIG. 3.

FIG. 18 is a structural layout diagram of the light shielding layer, the first active layer, the first conductive layer, the second conductive layer, the second active layer, and the third conductive layer in FIG. 3.

FIG. 19 is a structural layout diagram of the light shielding layer, the first active layer, the first conductive layer, the second conductive layer, the second active layer, the third conductive layer, and the fourth conductive layer in FIG. 3.

FIG. 20 is a structural layout diagram of the light shielding layer, the first active layer, the first conductive layer, the second conductive layer, the second active layer, the third conductive layer, the fourth conductive layer, and the fifth conductive layer in FIG. 3.

FIG. 21 is a partial cross-sectional view of the display panel shown in FIG. 3 taken along dotted line AA.

FIG. 22 is a schematic structural diagram of a display panel according to another exemplary embodiment of this disclosure.

FIG. 23 is a layout structure of the light shielding layer in the optical signal collection area.

FIG. 24 is a layout structure of the light shielding layer in the normal display area.

FIG. 25 is another layout structure of the light shielding layer in the optical signal collection area.

FIG. 26 is a schematic structural diagram of a display panel according to another exemplary embodiment of this disclosure.

FIG. 27 is a layout structure of the light shielding layer in the remaining display area of the display panel shown in FIG. 26.

### DETAILED DESCRIPTION

Exemplary embodiments will now be described more fully with reference to the accompanying drawings. Exemplary embodiments may, however, be embodied in many forms and should not be construed as limited to the embodiments set forth herein. Rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted.

The terms “a”, “an”, “the”, “said” and “at least one” are used to indicate the presence of one or more elements/components/etc.; the terms “comprise/include” and “have” are used to indicate an open inclusion and means that there may be additional elements/components/etc. in addition to the listed elements/components/etc.

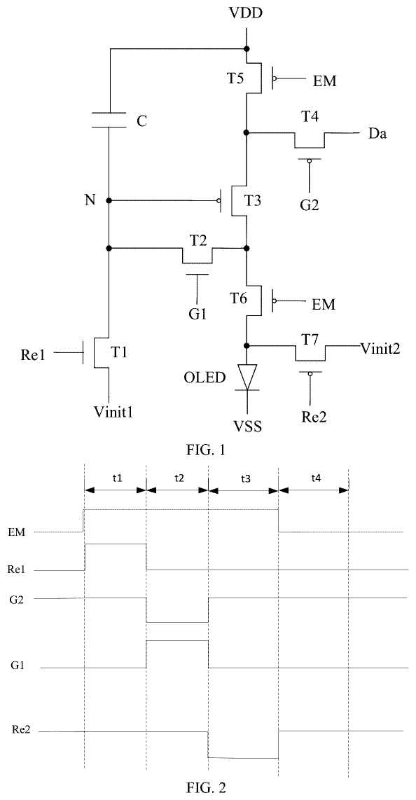

As shown in FIG. 1, it is a circuit structure diagram of a pixel driving circuit in the related art. The pixel driving circuit may include: a driving transistor T3, a first transistor T1, a second transistor T2, a fourth transistor T4, a fifth transistor T5, a sixth transistor T6, a seventh transistor T7, and a capacitor C. Herein, the first electrode of the fourth transistor T4 is connected to the data signal terminal Da, the second electrode thereof is connected to the first electrode of the driving transistor T3, and the gate thereof is connected to the second gate driving signal terminal G2. The first electrode of the fifth transistor T5 is connected to the first power supply terminal VDD, the second electrode thereof is connected to the first electrode of the driving transistor T3, and the gate thereof is connected to the enable signal terminal EM. The gate of the driving transistor T3 is connected to the node N. The first electrode of the second transistor T2 is connected to the node N, the second electrode thereof is connected to the second electrode of the driving transistor T3, and the gate thereof is connected to the first gate driving signal terminal G1. The first electrode of the sixth transistor T6 is connected to the second electrode of the driving transistor T3, the second electrode thereof is connected to the first electrode of the seventh transistor T7, and the gate thereof is connected to the enable signal terminal EM. The second electrode of the seventh transistor T7 is connected to the second initial signal terminal Vinit2, and the gate thereof is connected to the second reset signal terminal Re2. The first electrode of the first transistor T1 is connected to the node N, the second electrode thereof is connected to the first initial signal terminal Vinit1, and the gate thereof is connected to the first reset signal terminal Re1. The first electrode of the capacitor C is connected to the node N, and the second electrode thereof is connected to the first power supply terminal VDD. The pixel driving circuit can be connected to a light emitting unit OLED and configured to drive the light emitting unit OLED to emit light, and the light emitting unit OLED can be connected between the second electrode of the sixth transistor T6 and the second power supply terminal VSS. Herein, the first transistor T1 and the second transistor T2 can be N-type transistors, for example, the first transistor T1 and the second transistor T2 can be N-type metal oxide transistors. The N-type transistor has a smaller leakage current, so that the leakage current of the node N through the first transistor T1 and the second transistor T2 can be reduced during the light emitting stage. In addition, the driving transistor T3, the fourth transistor T4, the fifth transistor T5, the sixth transistor T6, and the seventh transistor T7 can be P-type transistors, for example, the driving transistor T3, the fourth transistor T4, the fifth transistor T5, the sixth transistor T6, and the seventh transistor T7 can be P-type low-temperature polycrystalline silicon (LTPS) transistors. The P-type LTPS transistor has a higher carrier mobility, which is conducive to realizing a display panel with high resolution, high response speed, high pixel density, and high aperture ratio. The first initial signal terminal and the second initial signal terminal can output the same or different voltage signals according to actual conditions.

As shown in FIG. 2, it is a timing diagram of each node in a driving method of the pixel driving circuit in FIG. 1. Herein, G1 represents the timing of the first gate driving signal terminal G1, G2 represents the timing of the second gate driving signal terminal G2, Re1 represents the timing of the first reset signal terminal Re1, Re2 represents the timing of the second reset signal terminal Re2, and EM represents the timing of the enable signal terminal EM. The driving method of the pixel driving circuit may include a first reset stage t1, a compensation stage t2, a second reset stage t3, and a light emitting stage t4. In the first reset stage t1, the first reset signal terminal Re1 outputs a high-level signal, the first transistor T1 is turned on, and the first initial signal terminal Vinit1 inputs an initial signal to the node N. In the compensation stage t2, the first gate driving signal terminal G1 outputs a high-level signal, the second gate driving signal terminal G2 outputs a low-level signal, the fourth transistor T4 and the second transistor T2 are turned on; the data signal terminal Da outputs a data signal to write a voltage Vdata+Vth to the node N, where Vdata is the voltage of the data signal and Vth is the threshold voltage of the driving transistor T3. In the second reset stage t3, the second reset signal terminal Re2 outputs a low-level signal, the seventh transistor T7 is turned on, and the second initial signal terminal Vinit2 inputs an initial signal to the second electrode of the sixth transistor T6. In the light emitting stage t4, the enable signal terminal EM outputs a low-level signal, the sixth transistor T6 and the fifth transistor T5 are turned on, and the driving transistor T3 emits light under the action of the voltage Vdata+Vth stored in the capacitor C.

The output current formula of the driving transistor is as follows:

I=(μWCox/2L)(Vgs−Vth)²

Herein, I is the output current of the driving transistor; is the carrier mobility; Cox is the gate capacitance per unit area, W is the channel width of the driving transistor, L is the channel length of the driving transistor, Vgs is the gate-source voltage difference of the driving transistor, and Vth is the threshold voltage of the driving transistor.

According to the above output current formula of the driving transistor, if the gate voltage Vdata+Vth and the source voltage Vdd of the driving transistor in the pixel driving circuit according to this disclosure are substituted into the above formula, the output current I of the driving transistor in the pixel driving circuit according to this disclosure can be derived as I=(μWCox/2L)(Vdata+Vth−Vdd−Vth)². The influence of the threshold of the driving transistor on its output current can be avoided in this pixel driving circuit.

Some exemplary embodiments provide a display panel, which may include a base substrate, a light shielding layer, a first active layer, a first conductive layer, a second conductive layer, a second active layer, a third conductive layer, a fourth conductive layer, a fifth conductive layer, an electrode layer, and a pixel defining layer stacked in sequence, where an insulating layer(s) may be arranged between adjacent conductive layers.

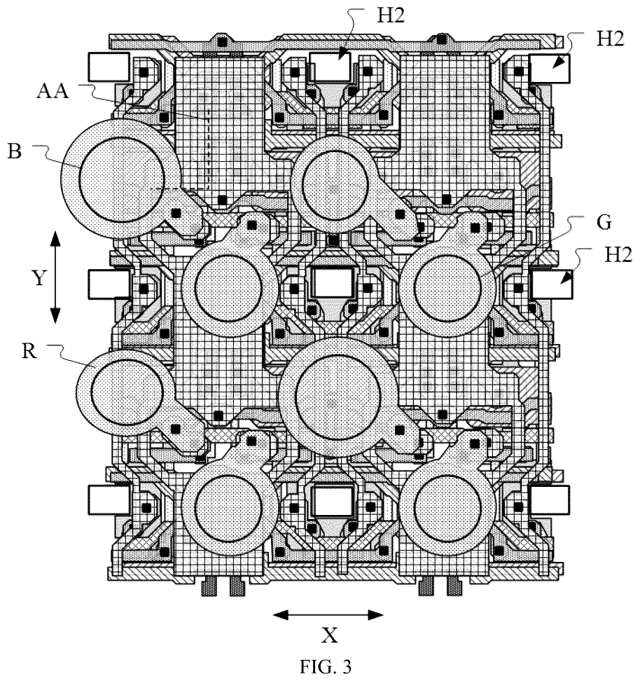

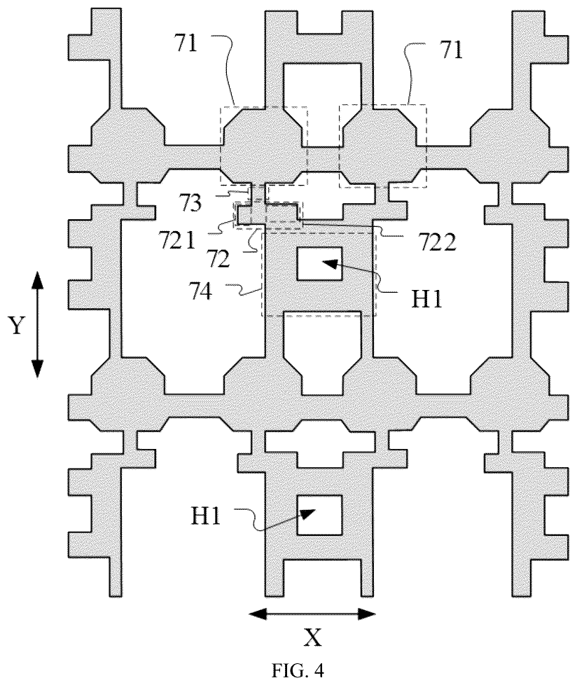

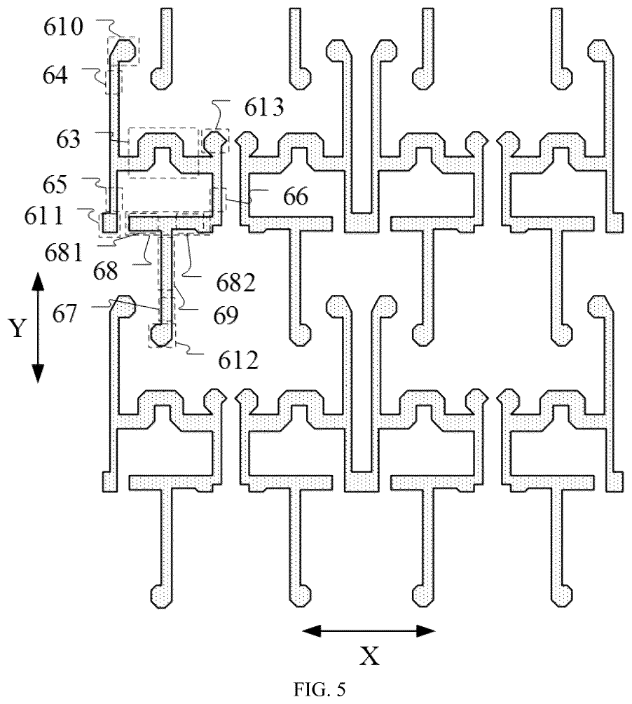

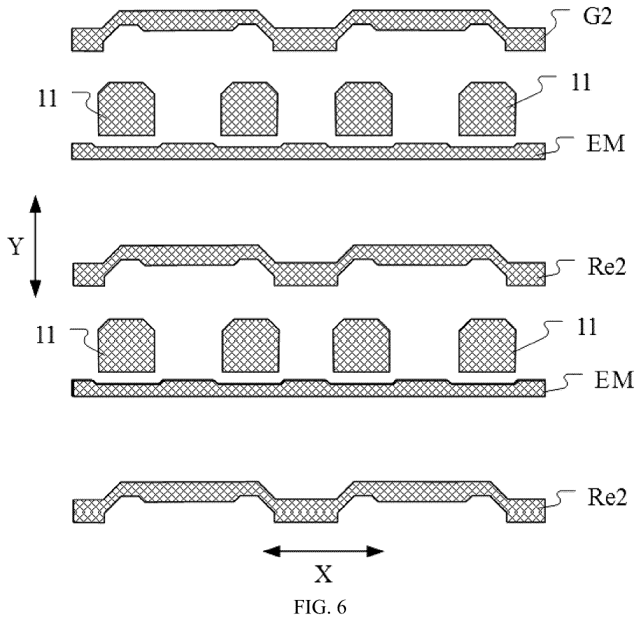

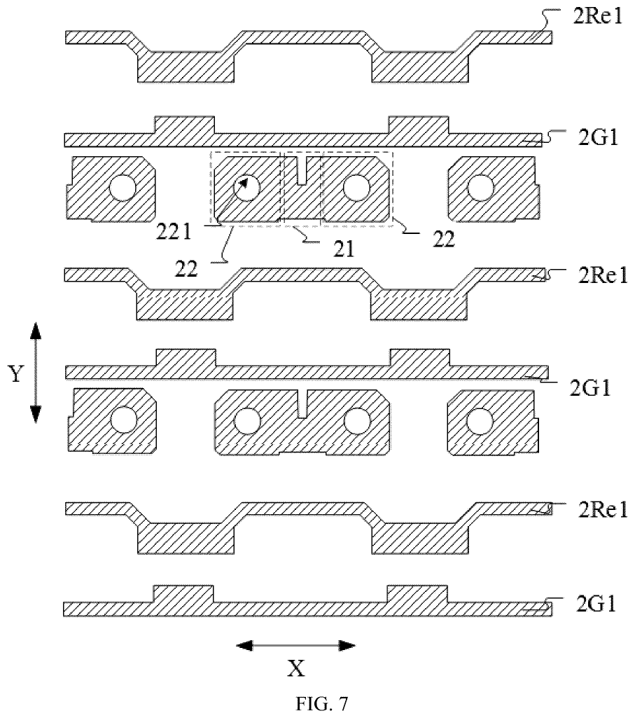

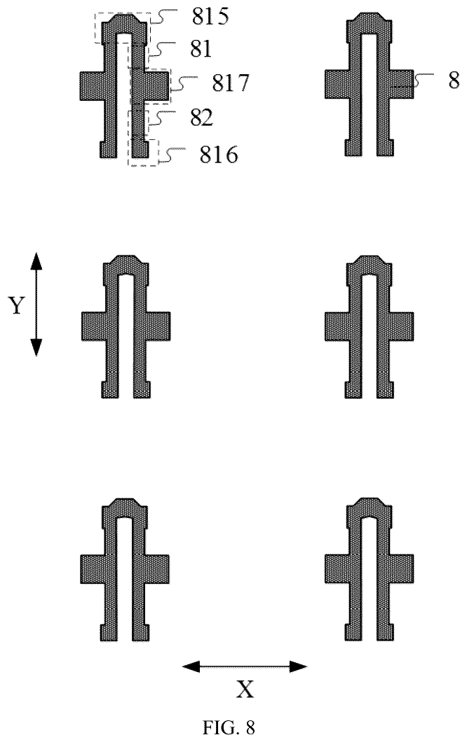

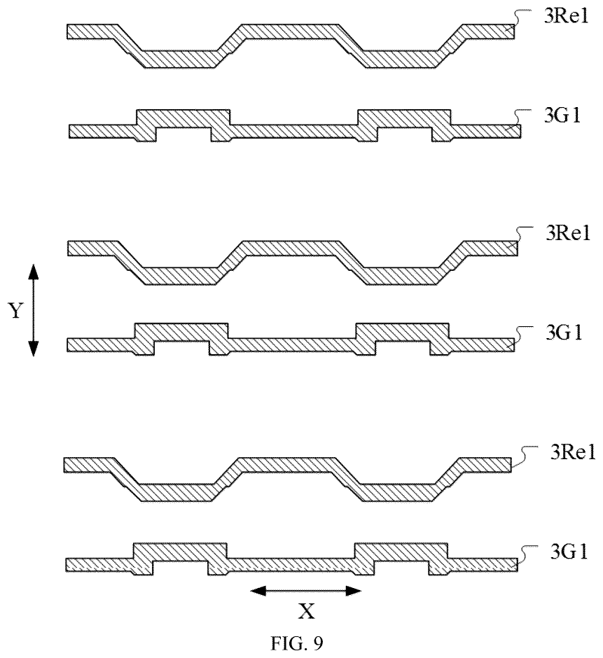

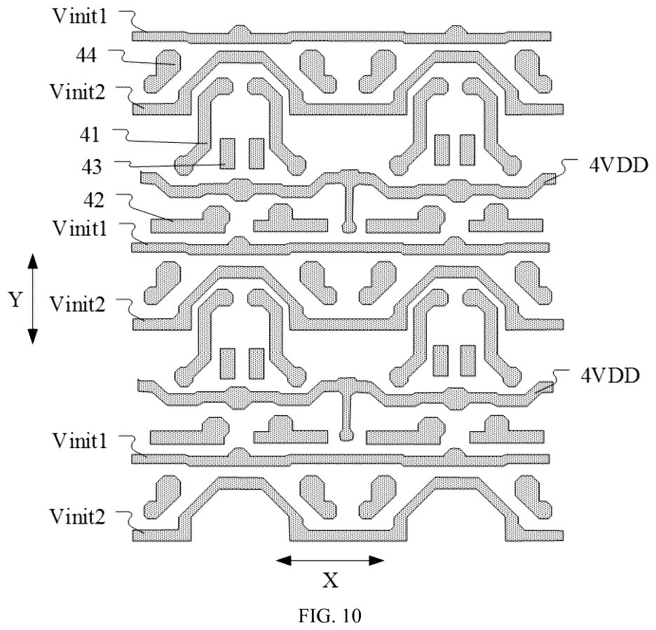

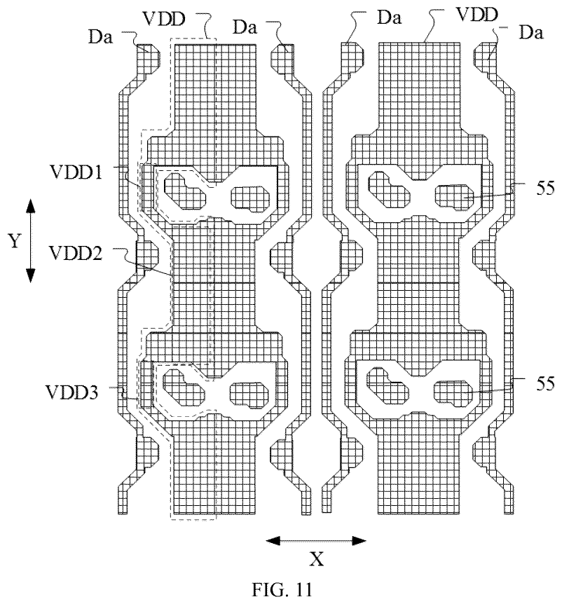

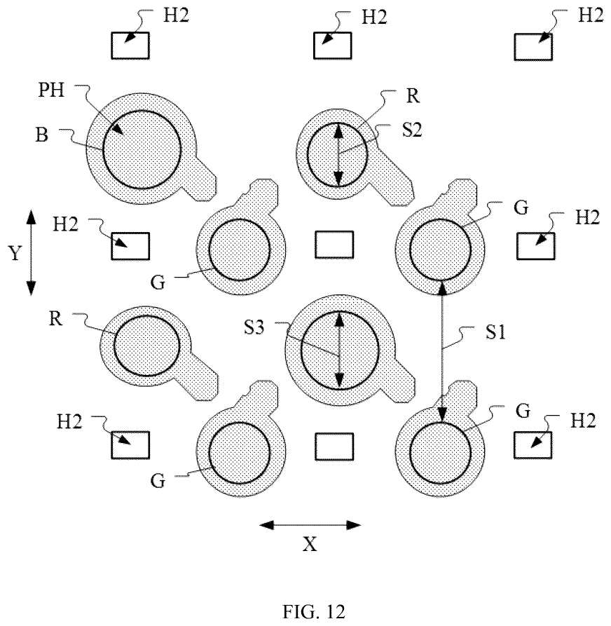

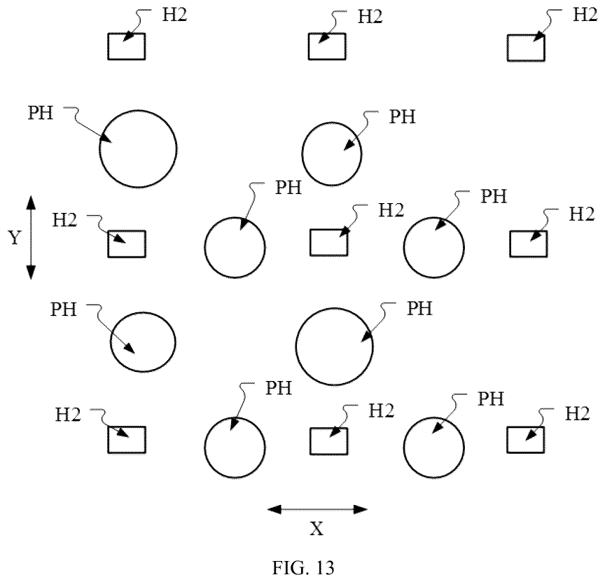

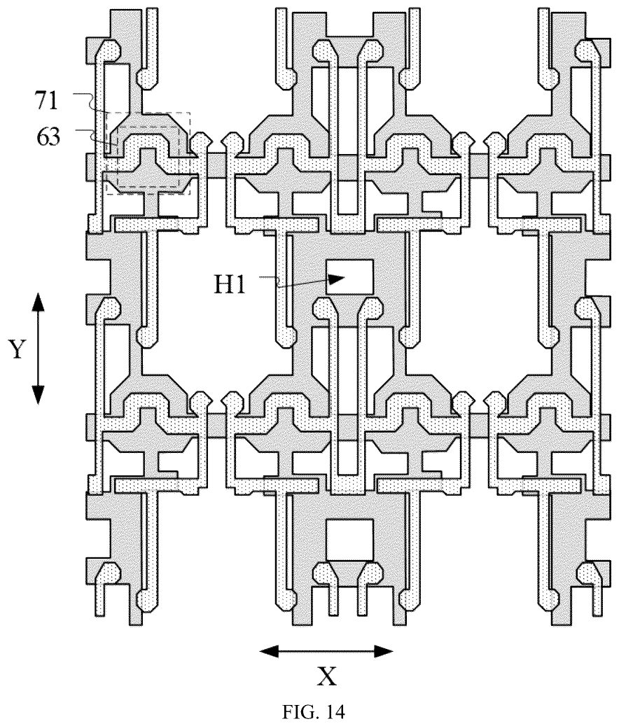

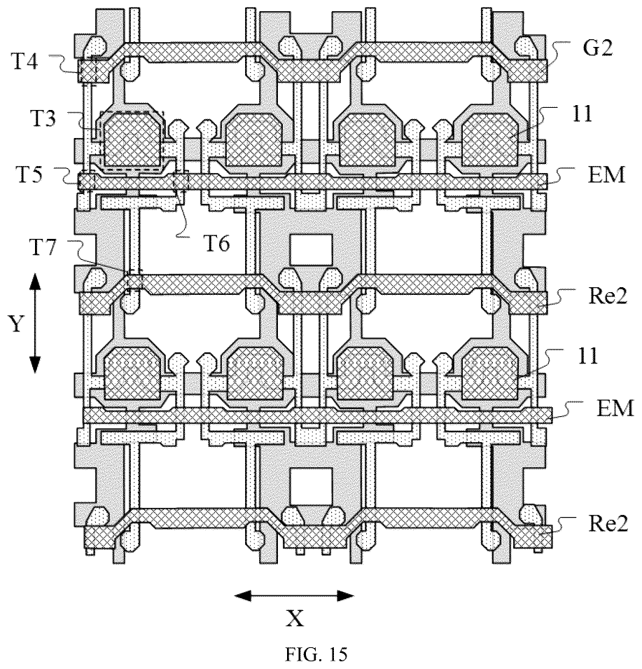

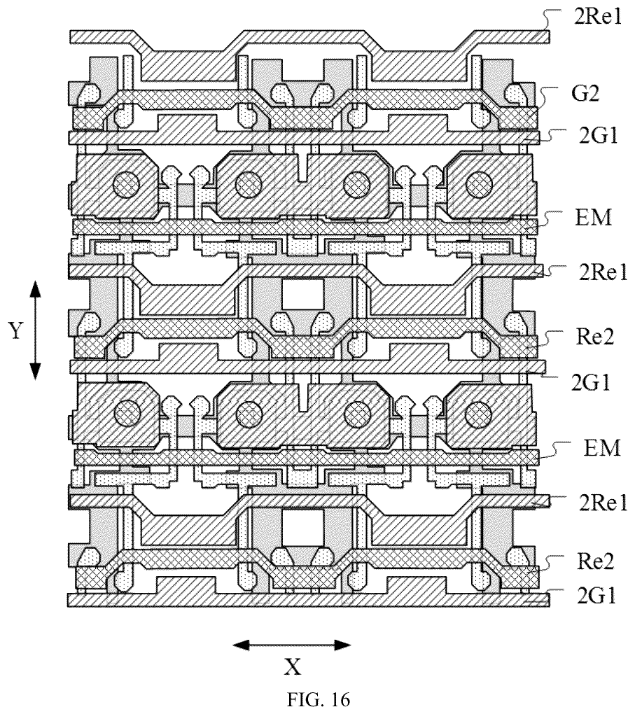

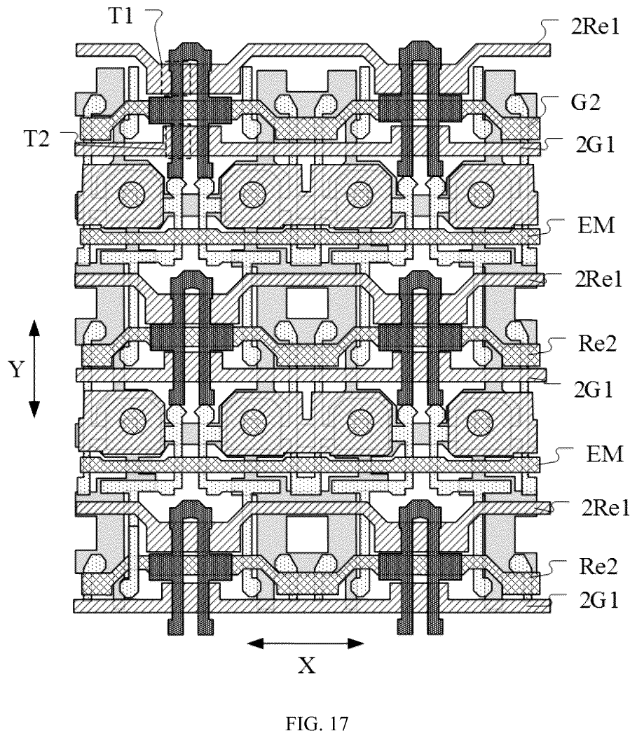

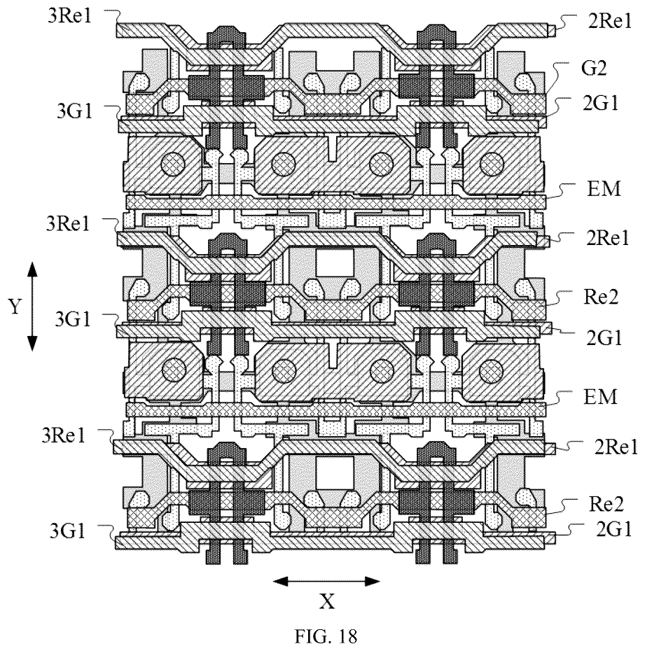

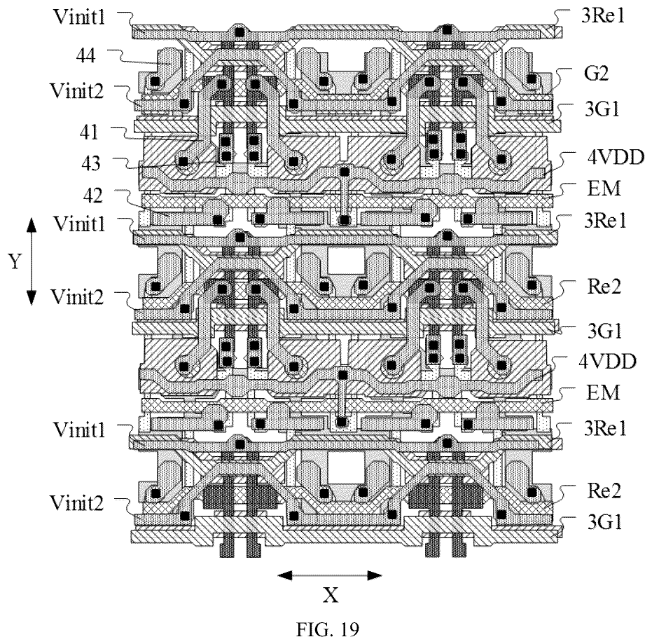

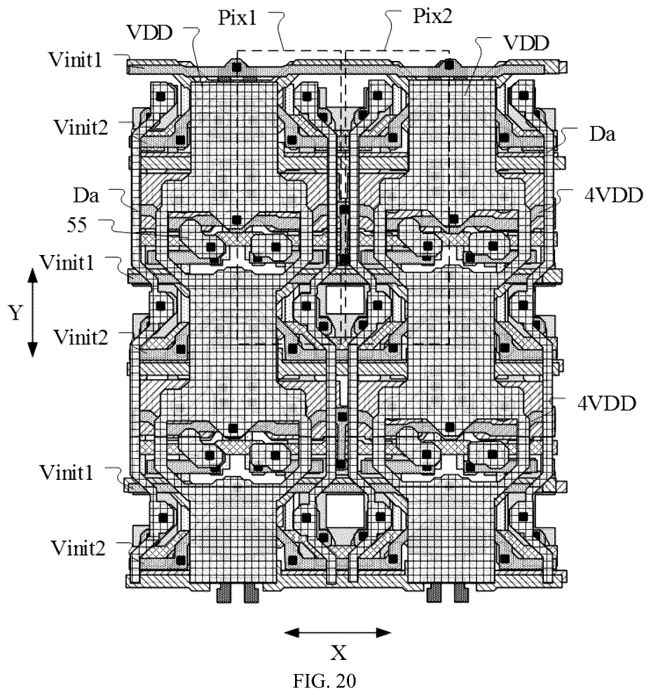

As shown in FIG. 3-FIG. 20, FIG. 3 is a structural layout diagram of a display panel according to an exemplary embodiment of this disclosure, FIG. 4 is a structural layout diagram of the light shielding layer in FIG. 3, FIG. 5 is a structural layout diagram of the first active layer in FIG. 3, FIG. 6 is a structural layout diagram of the first conductive layer in FIG. 3, FIG. 7 is a structural layout diagram of the second conductive layer in FIG. 3, FIG. 8 is a structural layout diagram of the second active layer in FIG. 3, FIG. 9 is a structural layout diagram of the third conductive layer in FIG. 3, FIG. 10 is a structural layout diagram of the fourth conductive layer in FIG. 3, FIG. 11 is a structural layout diagram of the fifth conductive layer in FIG. 3, FIG. 12 is a structural layout diagram of the electrode layer and the pixel defining layer in FIG. 3, FIG. 13 is a structural layout diagram of the pixel defining layer in FIG. 3, FIG. 14 is a structural layout diagram of the light shielding layer and the first active layer in FIG. 3, FIG. 15 is a structural layout diagram of the light shielding layer, the first active layer, and the first conductive layer in FIG. 3, FIG. 16 is a structural layout diagram of the light shielding layer, the first active layer, the first conductive layer, and the second conductive layer in FIG. 3, FIG. 17 is a structural layout diagram of the light shielding layer, the first active layer, the first conductive layer, the second conductive layer, and the second active layer in FIG. 3, FIG. 18 is a structural layout diagram of the light shielding layer, the first active layer, the first conductive layer, the second conductive layer, the second active layer, and the third conductive layer in FIG. 3, FIG. 19 is a structural layout diagram of the light shielding layer, the first active layer, the first conductive layer, the second conductive layer, the second active layer, the third conductive layer, and the fourth conductive layer in FIG. 3, FIG. 20 is a structural layout diagram of the light shielding layer, the first active layer, the first conductive layer, the second conductive layer, the second active layer, the third conductive layer, the fourth conductive layer, and the fifth conductive layer in FIG. 3. The display panel may include a plurality of pixel driving circuits shown in FIG. 1. As shown in FIG. 20, the plurality of pixel driving circuits may include a first pixel driving circuit Pix1 and a second pixel driving circuit Pix2 adjacently distributed in a first direction X, and the first pixel driving circuit Pix1 and the second pixel driving circuit Pix2 may be arranged in a mirror-symmetrical manner. The first pixel driving circuit Pix1 and the second pixel driving circuit Pix2 may form a repeating unit, and the display panel may include a plurality of repeating units arrayed in the first direction X and the second direction Y The first direction X and the second direction Y may intersect with each other, for example, the first direction may be a row direction, and the second direction may be a column direction.

As shown in FIG. 3, FIG. 4 and FIG. 14, the light shielding layer may include a plurality of first shielding parts 71, which are distributed in an array in the first direction X and the second direction Y The first shielding parts 71 adjacent in the first direction X are connected, and the first shielding parts 71 adjacent in the second direction Y are connected.

As shown in FIG. 3, FIG. 5, and FIG. 15, the first active layer may include a third active part 63, a fourth active part 64, a fifth active part 65, a sixth active part 66, a seventh active part 67, an eighth active part 68, a ninth active part 69, a tenth active part 610, an eleventh active part 611, a twelfth active part 612, and a thirteenth active part 613. The third active part 63 can be configured to form a channel region of the driving transistor T3; the fourth active part 64 can be configured to form a channel region of the fourth transistor T4; the fifth active part 65 can be configured to form a channel region of the fifth transistor T5; the sixth active part 66 can be configured to form a channel region of the sixth transistor T6; and the seventh active part 67 can be configured to form a channel region of the seventh transistor T7. The eighth active part 68 is connected between the sixth active part 66 and the seventh active part 67, the orthographic projection of the eighth active part 68 on the base substrate extends along the first direction X, and the size, in the first direction X, of the orthographic projection of the eighth active part 68 on the base substrate is greater than the size, in the second direction Y, of the orthographic projection of the eighth active part 68 on the base substrate. The ninth active part 69 is connected between the eighth active part 68 and the seventh active part 67, and the orthogonal projection of the ninth active part 69 on the base substrate extends along the second direction Y The tenth active part 610 is connected to an end of the fourth active part 64 away from the third active part 63. The eleventh active part 611 is connected to an end of the fifth active part 65 away from the third active part 63, and in the same repeating unit, two eleventh active parts 611 can be connected with each other. The twelfth active part 612 is connected to an end of the seventh active part 67 away from the sixth active part 66. The thirteenth active part 613 is connected between the third active part 63 and the sixth active part 66. The first active layer can be formed of polysilicon material, and accordingly, the driving transistor T3, the fourth transistor T4, the fifth transistor T5, the sixth transistor T6, and the seventh transistor T7 can be P-type LTPS thin film transistors (TFTs).

As shown in FIG. 14 and FIG. 15, the orthographic projection of the first light shielding part 71 on the base substrate covers the orthographic projection of the third active part 63 on the base substrate, and the first light shielding part 71 can shield the third active part 63 to reduce the influence of light on the characteristics of the driving transistor T3. As shown in FIG. 4, the light shielding layer can also include a second light shielding part 72 and a third light shielding part 73. The orthographic projection of the third light shielding part 73 on the base substrate extends along the second direction Y, and the third light shielding part 73 is connected between the first light shielding part 71 and the second light shielding part 72. The orthographic projection of the second light shielding part 72 on the base substrate at least partially overlaps with the orthographic projection of the eighth active part 68 on the base substrate, and the second light shielding part 72 and the eighth active part 68 can form a parasitic capacitor. Such arrangement can increase the parasitic capacitance of the second electrode of the sixth transistor T6 in FIG. 1, thereby improving the problem of reddening of the display panel under low grayscale. In some embodiments, the second light shielding part 72 may include a first light shielding subpart 721 and a second light shielding subpart 722. In the first direction X, the orthographic projections of the first light shielding subpart 721 and the second light shielding subpart 722 on the base substrate are located on both sides of the orthographic projection of the third light shielding part 73 on the base substrate. The orthographic projection of the first light shielding subpart 721 on the base substrate at least partially overlaps with the orthographic projection of the eighth active part 68 on the base substrate, and the orthographic projection of the second light shielding subpart 722 on the base substrate at least partially overlaps with the orthographic projection of the eighth active part 68 on the base substrate. As shown in FIG. 5, the eighth active part 68 may include a first active subpart 681 and a second active subpart 682. In the first direction X, the orthographic projections of the first active subpart 681 and the second active subpart 682 on the base substrate are located on both sides of the orthographic projection of the ninth active part 69 on the base substrate. The orthographic projection of the first active subpart 681 on the base substrate at least partially overlaps with the orthographic projection of the second light shielding part 72 on the base substrate, and the orthographic projection of the second active subpart 682 on the base substrate at least partially overlaps with the orthographic projection of the second light shielding part 72 on the base substrate.

As shown in FIG. 3, FIG. 6, and FIG. 15, the first conductive layer may include a first conductive part 11, a second gate line G2, an enable signal line EM, and a second reset signal line Re2. The second gate line G2 can be configured to provide the second gate driving signal terminal in FIG. 1; the enable signal line EM can be configured to provide the enable signal terminal in FIG. 1; and the second reset signal line Re2 can be configured to provide the second reset signal terminal in FIG. 1. The orthographic projection of the second gate line G2 on the base substrate, the orthographic projection of the enable signal line EM on the base substrate, and the orthographic projection of the second reset signal line Re2 on the base substrate can all extend along the first direction X. In some embodiments, the orthographic projection of the second gate line G2 on the base substrate covers the orthographic projection of the fourth active part 64 on the base substrate, and a partial structure of the second gate line G2 is configured to form the gate of the fourth transistor. The orthographic projection of the enable signal line EM on the base substrate covers the orthographic projection of the fifth active part 65 on the base substrate and the orthographic projection of the sixth active part 66 on the base substrate, and a partial structure of the enable signal line EM can be configured to form the gates of the fifth transistor T5 and the sixth transistor T6, respectively. The orthographic projection of the second reset signal line Re2 on the base substrate can cover the orthographic projection of the seventh active part 67 on the base substrate, and a partial structure of the second reset signal line Re2 can be configured to form the gate of the seventh transistor T7. The orthographic projection of the first conductive part 11 on the base substrate covers the orthographic projection of the third active part 63 on the base substrate, and the first conductive part 11 can be configured to form the gate of the driving transistor T3 and the first electrode of the capacitor C. As shown in FIG. 15, the second gate line G2 in the pixel driving circuit of one row can be reused as the second reset signal line Re2 in the pixel driving circuit of its previous row. Such arrangement can improve the integration of the pixel driving circuit and reduce the layout area of the pixel driving circuit. The light shielding layer can be connected to a stable power supply terminal. For example, the light shielding layer can be connected to the first power supply terminal, the first initial signal terminal, the second initial signal terminal, and the like in FIG. 1. The first shielding part 71 can stabilize the voltage of the first conductive part 11, thereby reducing the voltage fluctuation of the gate of the driving transistor T3 during the light emitting stage. In addition, conductorization processing can be performed on the first active layer by using the first conductive layer as a mask in this display panel, that is, the area in the first active layer covered by the first conductive layer can form a channel region of the transistor, and the area therein not covered by the first conductive layer can form a conductor structure.

As shown in FIG. 3, FIG. 7, and FIG. 16, the second conductive layer may include a third reset signal line 2Re1, a third gate line 2G1, a plurality of second conductive parts 22, and a first connecting part 21. In some embodiments, the third reset signal line 2Re1 can be configured to provide the first reset signal terminal in FIG. 1, and the third gate line 2G1 can be configured to provide the first gate driving signal terminal in FIG. 1. The orthographic projection of the third reset signal line 2Re1 on the base substrate and the orthographic projection of the third gate line 2G1 on the base substrate can both extend along the first direction X. The orthographic projection of the second conductive part 22 on the base substrate can at least partially overlap with the orthographic projection of the first conductive part 11 on the base substrate, and the second conductive part 22 can be configured to form the second electrode of the capacitor C. The first connecting part 21 is connected between two second conductive parts 22 in the same repeating unit. It should be understood that in other exemplary embodiments, in two repeating units adjacent in the first direction X, two adjacent second conductive parts can also be connected.

As shown in FIG. 3, FIG. 8 and FIG. 17, the second active layer may include a plurality of active subparts 8, the active subparts 8 include a first active part 81, a second active part 82, a fifteenth active part 815, a sixteenth active part 816 and a seventeenth active part 817. The first active part 81 may be configured to form a channel region of the first transistor T1; the second active part 82 may be configured to form a channel region of the second transistor T2; the fifteenth active part 815 is connected to an end of the first active part 81 away from the second active part 82, the sixteenth active part 816 is connected to an end of the second active part 82 away from the first active part 81, and the seventeenth active part 817 is connected between the first active part 81 and the second active part 82. In two repeating units adjacent in the first direction X, adjacent active subparts 8 share the same fifteenth active part 815. The second active layer may be formed of indium gallium zinc oxide, and accordingly, the first transistor T1 and the second transistor T2 may be N-type metal oxide thin film transistors. The orthographic projection of the third gate line 2G1 on the base substrate can cover the orthographic projection of the second active part 82 on the base substrate, and a partial structure of the third gate line 2G1 can be configured to form the bottom gate of the second transistor. The orthographic projection of the third reset signal line 2Re1 on the base substrate can cover the orthographic projection of the first active part 81 on the base substrate, and a partial structure of the third reset signal line 2Re1 can be configured to form the bottom gate of the first transistor T1. In other exemplary embodiments, the orthographic projection of the light shielding layer on the base substrate can also cover the orthographic projection of the active subpart 8 on the base substrate, thereby reducing the influence of light on the characteristics of the first transistor and the second transistor.

As shown in FIG. 3, FIG. 9, and FIG. 18, the third conductive layer may include a first reset signal line 3Re1 and a first gate line 3G1. The orthographic projection of the first reset signal line 3Re1 on the base substrate and the orthographic projection of the first gate line 3G1 on the base substrate may both extend along the first direction X. The first reset signal line 3Re1 may be configured to provide the first reset signal terminal in FIG. 1, the orthographic projection of the first reset signal line 3Re1 on the base substrate may cover the orthographic projection of the first active part 81 on the base substrate, and a partial structure of the first reset signal line 3Re1 may be configured to form the top gate of the first transistor T1. In addition, the first reset signal line 3Re1 may be connected to the third reset signal line 2Re1 through a via located in an edge wiring area of the display panel. The first gate line 3G1 may be configured to provide the first gate driving signal terminal in FIG. 1, the orthographic projection of the first gate line 3G1 on the base substrate may cover the orthographic projection of the second active part 82 on the base substrate, and a partial structure of the first gate line 3G1 may be configured to form the top gate of the second transistor T2. Moreover, the first gate line 3G1 may be connected to the third gate line 2G1 through a via located in the edge wiring area of the display panel. As shown in FIG. 3, FIG. 9 and FIG. 18, in the same pixel driving circuit, the first reset signal line 3Re1, the second gate line G2, the first gate line 3G1, the first conductive part 11, the enable signal line EM and the second reset signal line Re2 have their orthographic projections on the base substrate being sequentially distributed in the second direction Y Conductorization processing can be performed on the second active layer by using the third conductive layer as a mask in this display panel, that is, the area in the second active layer covered by the third conductive layer can form a channel region of the transistor, and the area therein not covered by the third conductive layer can form a conductor structure.

As shown in FIG. 3, FIG. 10, and FIG. 19, the fourth conductive layer may include a first bridge part 41, a second bridge part 42, a third bridge part 43, a fourth bridge part 44, a first initial signal line Vinit1, a second initial signal line Vinit2, and a first power connection line 4VDD. In some embodiments, the first bridge part 41 can be connected to the seventeenth active part 817 and the first conductive part 11 through vias (black squares in the figure), so as to connect the first electrode of the second transistor T2 and the gate of the driving transistor T3. An opening 221 may be formed on the second conductive part 22, and an orthographic projection, on the base substrate, of a via connected between the first conductive part 11 and the first bridge part 41 is located on the orthographic projection of the opening 221 on the base substrate, so that the via connected between the first conductive part 11 and the first bridge part 41 is insulated from the second conductive part 22. The second bridge part 42 can be connected to the eighth active part through a via, so as to connect the second electrode of the sixth transistor T6 and the second electrode of the seventh transistor T7. In some embodiments, the size, in the first direction X, of the orthographic projection of the second bridge part 42 on the base substrate is greater than the size, in the second direction Y, of the orthographic projection of the second bridge part 42 on the base substrate. The second bridge part 42 and the first initial signal line Vinit1 and other signal lines can form a lateral parasitic capacitance to further increase the parasitic capacitance of the second electrode of the sixth transistor. The third bridge part 43 can be connected to the sixteenth active part 816 and the thirteenth active part 613 through vias, respectively, so as to connect the second electrode of the second transistor T2 and the second electrode of the driving transistor T3. The fourth bridge part 44 can be connected to the tenth active part 410 through a via, so as to connect the first electrode of the fourth transistor T4. The orthographic projection of the first initial signal line Vinit1 on the base substrate extends along the first direction, and the first initial signal line Vinit1 is configured to provide the first initial signal terminal in FIG. 1. The first initial signal line Vinit1 can be connected to the fifteenth active part 815 through a via, so as to connect the first electrode of the first transistor T1. The orthographic projection of the second initial signal line Vinit2 on the base substrate may extend along the first direction X, and the second initial signal line Vinit2 may be configured to provide the second initial signal terminal in FIG. 1. The second initial signal line Vinit2 may be connected to the twelfth active part 612 through a via, so as to connect the first electrode of the seventh transistor T7. The orthographic projection of the first power connection line 4VDD on the base substrate may extend along the first direction X, and the first power connection line 4VDD may be connected to the first connecting part 21 and the eleventh active part 611 through vias, so as to connect the first electrode of the fifth transistor T5 and the second electrode of the capacitor C.

As shown in FIG. 3, FIG. 11, and FIG. 20, the fifth conductive layer may include a first power line VDD, a data line Da, and a fifth bridge part 55. The fifth bridge part 55 may be connected to the second bridge part 42 through a via, so as to connect the second electrode of the sixth transistor. The orthographic projection of the first power line VDD on the base substrate may extend along the second direction Y, and the first power line VDD is configured to provide the first power signal terminal in FIG. 1. The first power line VDD may include a first extension part VDD1, a second extension part VDD2, and a third extension part VDD3. The second extension part VDD2 is connected between the first extension part VDD1 and the third extension part VDD3, the size, in the first direction X, of the orthographic projection of the second extension part VDD2 on the base substrate may be greater than the size, in the first direction X, of the orthographic projection of the first extension part VDD1 on the base substrate, and the size, in the first direction X, of the orthographic projection of the second extension part VDD2 on the base substrate may be greater than the size, in the first direction X, of the orthographic projection of the third extension part VDD3 on the base substrate. In the two repeating units adjacent in the first direction X, the second extension parts VDD2 in the two adjacent first power lines VDD are connected, and the connected second extension parts VDD2 are connected to the first power connection line 4VDD through one or more vias. The first power line VDD and the first power connection line 4VDD can form a grid structure, and the power lines of the grid structure can reduce the voltage drop of the power signal thereon. The orthographic projection of the second extension part VDD2 on the base substrate can cover the orthographic projections of the first active part 81 and the second active part 82 on the base substrate, and the second extension part VDD2 can reduce the influence of light on the characteristics of the first transistor and the second transistor. The orthographic projection of the second extension part VDD2 on the base substrate can also cover the orthographic projection of the first bridge part 41 on the base substrate, and the second extension part VDD2 can stabilize voltage of and shield the first bridge part 41, so as to reduce the voltage fluctuation of the gate of the driving transistor T3 during the light emitting stage. As shown in FIG. 20, the connected second extension parts VDD2 are connected to the first power connection line 4VDD through a via, and the first power connection line 4VDD can be connected to the first connecting part 21 through a via. Such arrangement can reduce the number of vias, thereby saving the space occupied by the vias. The data line Da can be configured to provide the data signal terminal in FIG. 1, and the orthographic projection of the data line Da on the base substrate can extend along the second direction Y The data line Da can be connected to the fourth bridge part 44 through a via, so as to connect the data signal terminal and the first electrode of the fourth transistor.

As shown in FIG. 3, FIG. 12 and FIG. 13, the electrode layer includes a plurality of electrode parts: a first electrode part G, a second electrode part B and a third electrode part R, each of which can be connected to the fifth bridge part 55 through a via to connect the second electrode of the sixth transistor. A plurality of pixel openings PH are formed on the pixel defining layer, the pixel openings PH are arranged corresponding to the electrode parts, and the orthographic projection of the pixel openings PH on the base substrate coincides with the orthographic projection of the electrode parts on the base substrate. The first electrode part G can be configured to form the electrode part of the green light emitting unit in the display panel, the second electrode part B can be configured to form the electrode part of the blue light emitting unit in the display panel, and the third electrode part R can be configured to form the electrode part of the red light emitting unit. In the plurality of electrode parts connected to the same row of pixel driving circuits, the second electrode part B, the first electrode part G, the third electrode part R, and the first electrode part G are alternately distributed in the row direction X. In two adjacent columns of pixel driving circuits, the plurality of second electrode parts B and the plurality of third electrode parts R are connected to the same column of pixel driving circuits, and the second electrode parts B and the third electrode parts R connected to the same column of pixel driving circuits are alternately distributed in the column direction Y The plurality of first electrode parts G are connected to another column of pixel driving circuits, and the first electrode parts G connected to the same column of pixel driving circuits are alternately distributed in the column direction. The minimum distance S1, in the column direction, of the orthogonal projections, on the base substrate, of the two first electrode parts G connected to the adjacent rows of pixel driving circuits and the same column of pixel driving circuits is greater than the size S2, in the column direction, of the orthogonal projection of the third electrode part R on the base substrate; and/or the minimum distance S1, in the column direction, of the orthogonal projections, on the base substrate, of the two first electrode parts G connected to the adjacent rows of pixel driving circuits and the same column of pixel driving circuits is greater than the size S3, in the column direction, of the orthogonal projection of the second electrode part B on the base substrate.

As shown in FIG. 4, a first opening H1 may also be provided on the light shielding layer, the base substrate may include a light transmitting area, the orthographic projections, on the base substrate, of the light shielding structures of all functional layers (including the first active layer, the first conductive layer, the second conductive layer, the second active layer, the third conductive layer, the fourth conductive layer, the fifth conductive layer, the electrode layer, and the insulating layers between the above layers) between the base substrate and the pixel defining layer are located outside the light transmitting area, and the orthographic projection of the first opening H1 on the base substrate is located in the light transmitting area. Based on the principle of pinhole imaging, the optical signal located on one side of the display panel can be projected/imaged on the other side of the display panel through the first opening H1, so that fingerprint recognition, under-screen camera and other technologies can be achieved by the display device using the display panel. In addition, the light shielding layer around the first opening H1 can reduce the influence, on the pinhole imaging effect, of stray light formed by the light shielding structure between the base substrate and the pixel defining layer. Herein, the light shielding structure may refer to a structure with a transmittance of less than 50% in the stacking direction of the display panel.

As shown in FIG. 4, the light shielding layer may further include a fourth light shielding part 74, which is provided corresponding to the repeating unit. The fourth light shielding part 74 is connected to the two second light shielding parts 72 in the repeating unit corresponding thereto, and is connected to an end of the second light shielding part 72 away from the first light shielding part 71. The first opening H1 is formed on the fourth light shielding part 74. The edge of the fourth light shielding part 74 close to the second light shielding part 72 may further form a lateral capacitor with the eighth active part 68, thereby further increasing the parasitic capacitance of the second electrode of the sixth transistor T6.

As shown in FIG. 3, FIG. 4 and FIG. 20, the orthographic projection of the first opening H1 on the base substrate can be located between the orthographic projections of the first reset signal line 3Re1 and the second gate line G2 on the base substrate in the same pixel driving circuit. The orthographic projection of the first opening H1 on the base substrate is located between the orthographic projections, on the base substrate, of two adjacent data lines Da in the same repeating unit.

In some exemplary embodiments, the area of the orthographic projection of the first opening H1 on the base substrate may be smaller than the area of the orthographic projection of the first light shielding part 71 on the base substrate. The area of the orthographic projection of the first light shielding part 71 on the base substrate may be 2-5 times the area of the orthographic projection of the first opening H1 on the base substrate. For example, the area of the orthographic projection of the first light shielding part 71 on the base substrate may be 2 times, 3 times, 4 times, 5 times, etc., the area of the orthographic projection of the first opening H1 on the base substrate.

It should be understood that in other exemplary embodiments, the pixel driving circuit can also be other structures, and accordingly, the layout structure of the display panel can also be other structures. As long as a first opening is formed on the light shielding layer, pinhole imaging can be achieved through the first opening located on the light shielding layer, so that fingerprint recognition, under-screen camera and other technologies can be achieved based on the display device using the display panel.

As shown in FIG. 3 and FIG. 13, the pixel defining layer PDL may be black, a second opening H2 may be further formed on the pixel defining layer, and the orthographic projection of the second opening H2 on the base substrate may also be located in the light transmitting area. The second opening H2 and/or the first opening H1 may form the pinhole required for pinhole imaging. The orthographic projection of the second opening H2 on the base substrate may coincide with the orthographic projection of the first opening H1 on the base substrate. Alternatively, the orthographic projection area of the second opening H2 on the base substrate is greater than the orthographic projection area of the first opening H1 on the base substrate, and the orthographic projection of the second opening H2 on the base substrate covers the orthographic projection of the first opening H1 on the base substrate. Alternatively, the orthographic projection area of the first opening H1 on the base substrate is greater than the orthographic projection area of the second opening H2 on the base substrate, and the orthographic projection of the first opening H1 on the base substrate covers the orthographic projection of the second opening H2 on the base substrate.

In other exemplary embodiments, the display panel may further include a color filter layer located on a side of the pixel defining layer away from the base substrate, and the black matrix on the color filter layer may be formed with a third imaging hole. One or more of the first opening, the second opening, and the third imaging hole may form the pinhole(s) required for pinhole imaging.

It should be noted that, as shown in FIG. 3, FIG. 19, and FIG. 20, the black squares illustrated on a side of the fourth conductive layer away from the base substrate represents vias used by the fourth conductive layer to connect other layers at the side facing the base substrate; the black squares illustrated on a side of the fifth conductive layer away from the base substrate represents vias used by the fifth conductive layer to connect other layers at the side facing the base substrate; and the black squares illustrated on a side of the electrode layer away from the base substrate represents vias used by the electrode layer to connect other layers at the side facing the base substrate. The black squares indicate the positions of the vias, and different vias indicated by black squares at different positions may penetrate different insulating layers.

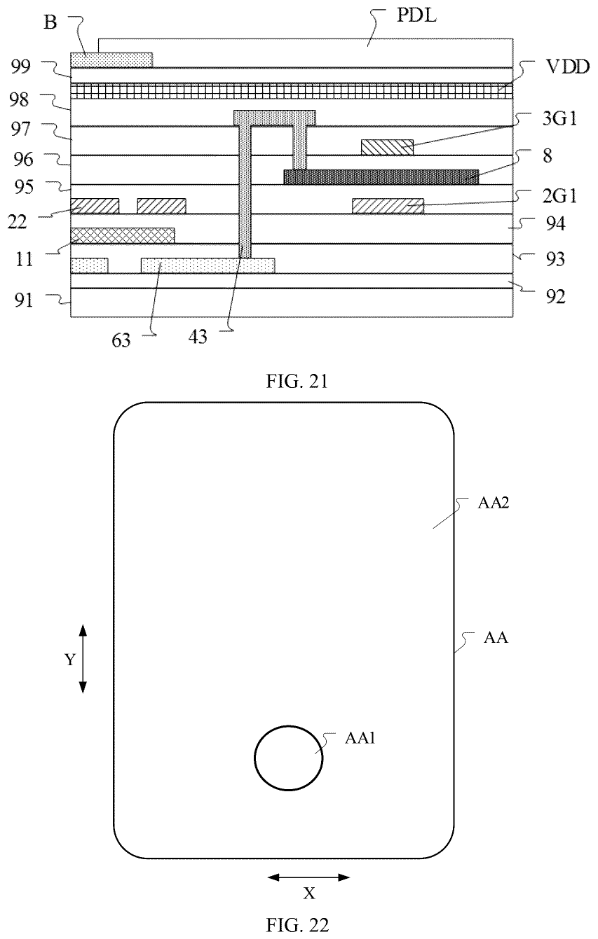

As shown in FIG. 21, it is a partial cross-sectional view of the display panel shown in FIG. 3 taken along the dotted line AA. The display panel may further include a first buffer layer 92, a first insulating layer 93, a second insulating layer 94, a second buffer layer 95, a third insulating layer 96, a dielectric layer 97, a first planarization layer 98, and a second planarization layer 99. In some embodiments, the base substrate 91, the light shielding layer, the first buffer layer 92, the first active layer, the first insulating layer 93, the first conductive layer, the second insulating layer 94, the second conductive layer, the second buffer layer 95, the second active layer, the third insulating layer 96, the third conductive layer, the dielectric layer 97, the fourth conductive layer, the first planarization layer 98, the fifth conductive layer, the second planarization layer 99, the electrode layer, and the pixel defining layer PDL are stacked in sequence. The first buffer layer 92 and the second buffer layer 95 may include one or more layers of silicon oxide layer and silicon nitride layer. The first insulating layer 93, the second insulating layer 94 and the third insulating layer 96 may include one or more layers of silicon oxide layer and silicon nitride layer. The dielectric layer 97 may include a silicon nitride layer. Materials of the first planarization layer 98 and the second planarization layer 99 may be organic materials, such as polyimide (PI), polyethylene terephthalate (PET), polyethylene naphthalate (PEN), silicon-glass bonding structure (SOG) and the like. The base substrate 91 may include a glass substrate, a barrier layer and a polyimide layer stacked in sequence, where the barrier layer may be an inorganic material. Materials of the first conductive layer, the second conductive layer and the third conductive layer may be one or an alloy of molybdenum, aluminum, copper, titanium and niobium, or a molybdenum/titanium alloy or laminate, or the like. Materials of the fourth conductive layer and the fifth conductive layer may include metal materials, such as one or an alloy of molybdenum, aluminum, copper, titanium and niobium, or a molybdenum/titanium alloy or laminate, or a titanium/aluminum/titanium laminate, or the like. The electrode layer may include an indium tin oxide layer and a silver layer. The square resistance of any one of the first conductive layer, the second conductive layer and the third conductive layer may be greater than the square resistance of any one of the fourth conductive layer and the fifth conductive layer.

It should be noted that the scale of the drawings in this disclosure can be used as a reference in the actual process, but is not limited thereto. For example, the width-to-length ratio of the channel, the thickness and spacing of each film layer, and the width and spacing of each signal line can be adjusted according to actual needs. The number of pixels in the display substrate and the number of sub-pixels in each pixel are not limited to the number shown in the drawings. The drawings described in this disclosure are only structural schematic diagrams. In addition, the terms “first”, “second” and the like are only used to define different structural names, rather than limiting a specific order and quantity. In the exemplary embodiments, when referring to that the orthographic projection of a certain structure on the base substrate extends in a certain direction, it can be understood as the orthographic projection of the structure on the base substrate extending along the direction in straight or bended manner. The transistor refers to an element including at least three terminals: a gate, a drain and a source. The transistor has a channel region between the drain (drain electrode terminal, drain region or drain electrode) and the source (source electrode terminal, source region or source electrode), and the current can flow through the drain, the channel region and the source. In the exemplary embodiments, the channel region refers to a region where the current mainly flows. In the exemplary embodiments, the first electrode may be a drain electrode and the second electrode may be a source electrode; or the first electrode may be the source electrode and the second electrode may be the drain electrode. In the case of using transistors with opposite polarities or when the current direction changes during circuit operation, the functions of the “source (electrode)” and the “drain (electrode)” are sometimes interchanged. Therefore, in the exemplary embodiments, the “source (electrode)” and the “drain (electrode)” may be interchanged. In addition, the gate may also be referred to as a control electrode.

As shown in FIG. 22, it is a schematic diagram of the structure of the display panel according to another exemplary embodiment of this disclosure. The display panel may include a display area AA, and the display area AA may include an optical signal collection area AA1 and a normal display area AA2 outside the optical signal collection area AA1. In some embodiments, the optical signal collection area AA1 may be in a circular, rectangular, triangular, polygonal or other shape. The optical signal located on one side of the display panel can be imaged on the other side of the display panel through the first opening H1 located in the optical signal collection area AA1. The optical signal collection area AA1 can be used as a fingerprint recognition area, an under-screen camera area, or the like.

In some exemplary embodiments, the layout structures in the optical signal collection area AA1 and the normal display area AA2 can be as shown in FIG. 3. The light shielding layers in the optical signal collection area AA1 and the normal display area AA2 have the same pattern shape, so that different areas of the display panel have the same parasitic capacitance distribution. Such arrangement can improve the display uniformity of the display panel.

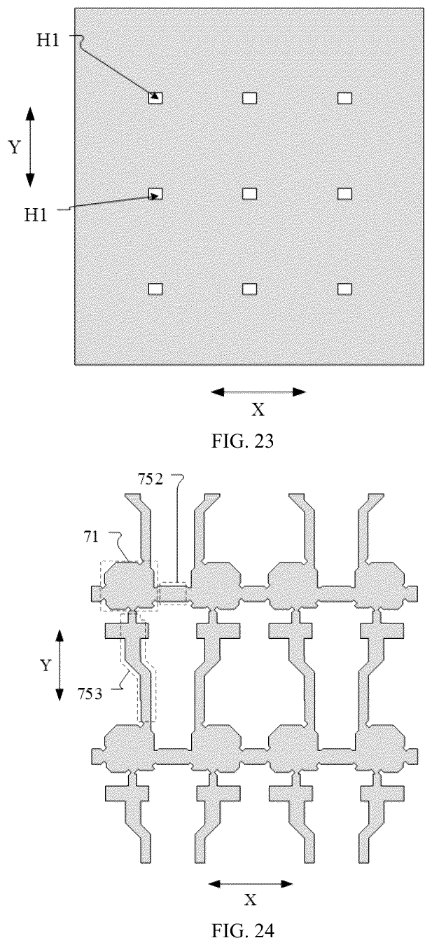

In some other exemplary embodiments, the orthographic projections of the light shielding layers in the optical signal collection area AA1 and the normal display area AA2 on the base substrate may have different pattern shapes. For example, as shown in FIG. 23 and FIG. 24, FIG. 23 is the layout structure of the light shielding layer in the optical signal collection area, and FIG. 24 is the layout structure of the light shielding layer in the normal display area.

As shown in FIG. 23, the light shielding layer located in the optical signal collection area is provided as an entire surface except for the first opening H1. Such arrangement can make the first opening in the optical signal collection area have a better imaging effect. As shown in FIG. 24, the light shielding layer located in the normal display area may include: a first light shielding part 71, a second connecting part 752, and a third connecting part 753. The orthographic projection of the second connecting part 752 on the base substrate extends along the first direction X and is connected between the first light shielding parts 71 adjacent to each other in the first direction X. The orthographic projection of the third connecting part 753 on the base substrate extends along the second direction Y and is connected between the first light shielding parts 71 adjacent to each other in the second direction Y In the normal display area, the ratio of the orthographic projection area of the hollow structure of the light shielding layer on the base substrate to the orthographic projection area of its solid structure on the base substrate is K1. In the optical signal collection area, the ratio of the orthographic projection area of the hollow structure of the light shielding layer on the base substrate to the orthographic projection area of its solid structure on the base substrate is K2, where K1 may be greater than K2. Such arrangement can effectively improve the problem of electrostatic damage to the device caused by the large area covering of the light shielding layer in the normal display area.

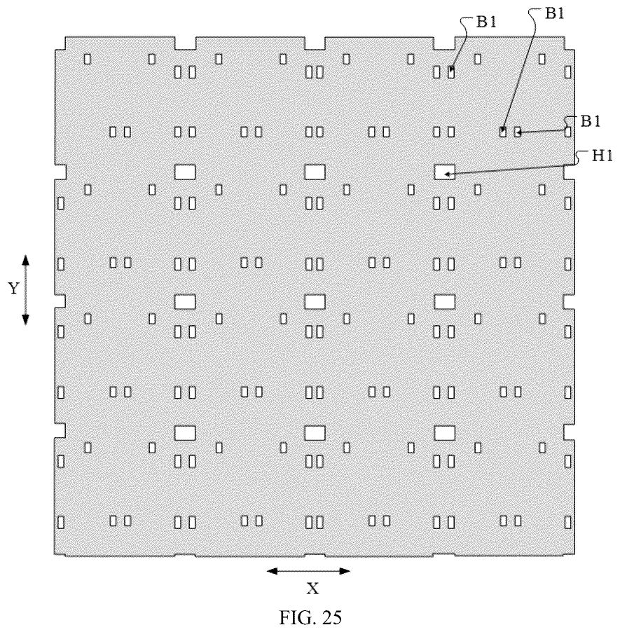

As shown in FIG. 25, another layout structure of the light shielding layer in the optical signal collection area is shown. A plurality of first openings B1 are formed on the light shielding layer in the optical signal collection area. The first openings B1 are arranged corresponding to the active parts for forming the transistor channel regions in the display panel. The orthographic projection of the first opening B1 on the base substrate covers the orthographic projection of the corresponding active part on the base substrate. The active part for forming the transistor channel region may include a first active part 81, a second active part 82, a third active part 63, a fourth active part 64, a fifth active part 65, a sixth active part 66, and a seventh active part 67. Forming the first openings B1 on the light shielding layer can reduce the parasitic capacitance between the light shielding layer and the transistor channel region, thereby reducing the influence of the parasitic capacitance on the transistor characteristics.

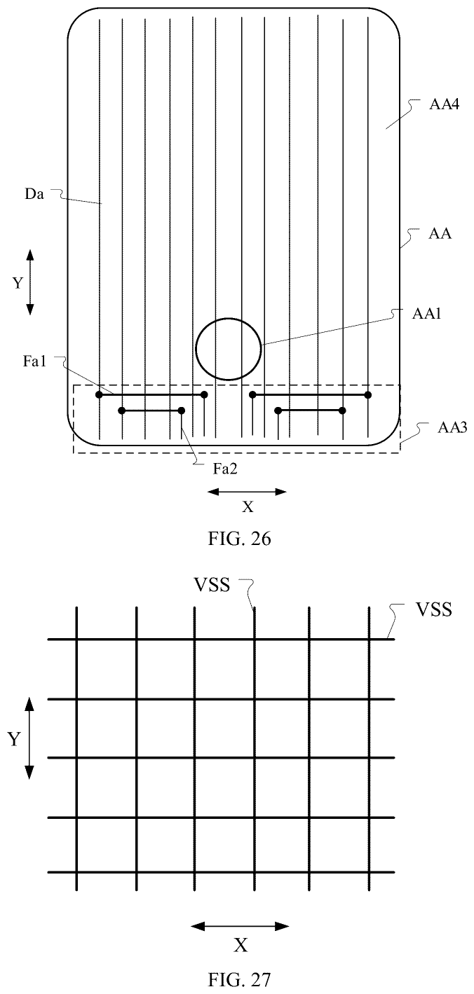

In some other exemplary embodiments, the light shielding layer may also be located at any other position between the base substrate and the pixel defining layer. For example, the light shielding layer may be located at the conductive layer where the fan-out line added in the FIP (Fanout In Panel) technology is located. As shown in FIG. 26, it is a schematic diagram of the structure of the display panel according to another exemplary embodiment of this disclosure, and the display panel includes a display area AA, where the display area AA includes a fan-out area AA3, an optical signal collection area AA1, and a remaining display area AA4 located outside the fan-out area AA3 and the optical signal collection area AA1. The display panel may include a plurality of data lines Da, a plurality of first data fan-out lines Fa1, and a plurality of second data fan-out lines Fa2. The plurality of data lines Da are located in the display area AA, and the orthographic projections of the data lines Da on the base substrate are spaced along the first direction X and extend along the second direction Y The plurality of first data fan-out lines Fa1 are located in the fan-out area AA3, and the orthographic projections of the first data fan-out lines Fa1 on the base substrate are spaced along the second direction Y and extend along the first direction X. The first data fan-out lines Fa1 are arranged corresponding to the data lines Da, and the first data fan-out lines Fa1 are connected to the corresponding data lines Da. The plurality of second data fan-out lines Fa2 are located in the fan-out area AA3, and the orthographic projections of the second data fan-out lines Fa2 on the base substrate are spaced along the first direction X and extend along the second direction Y The second data fan-out lines Fa2 are arranged corresponding to the first data fan-out lines Fa1, and the second data fan-out lines Fa2 are connected to the corresponding first data fan-out lines Fa1. The first data fan-out lines Fa1 may be located in the light shielding layer. The data line Da and the second data fan-out line Fa2 may be located in the fifth conductive layer, and the first data fan-out line Fa1 may be located in the sixth conductive layer added between the fifth conductive layer and the pixel defining layer.

In the display panel shown in FIG. 26, the layout structure of the light shielding layer in the optical signal collection area AA1 can be the same as the structure shown in FIG. 23 or FIG. 25. As shown in FIG. 27, it is the layout structure of the light shielding layer in the remaining display area AA4 of the display panel shown in FIG. 26. The light shielding layer located in the remaining display area AA4 may include a plurality of second power lines VSS, the orthographic projections of some second power lines VSS on the base substrate can extend along the first direction X, and the orthographic projections of some second power lines VSS on the base substrate can extend along the second direction Y The second power lines extending in different directions can intersect to form a grid structure, and the second power lines VSS forming the grid structure can be connected to the common electrode layer through vias, thereby reducing the voltage drop of the signal on the common electrode layer. In some embodiments, the common electrode layer is located on a side of the pixel defining layer away from the base substrate, and the common electrode layer is configured to form the second electrode of the light emitting unit. In some other exemplary embodiments, the second power lines of the light shielding layer located in the remaining display area AA4 can also extend in the same direction. In addition, in some other exemplary embodiments, the light shielding layer located in the remaining display area AA4 may also include other signal lines. For example, the light shielding layer located in the remaining display area AA4 may further include a second signal line. The second signal line and the first signal line located in different conductive layers may have their orthographic projections on the base substrate intersecting with each other, and the second signal line may be connected to the first signal line intersecting with it through a via. The second signal lines may form a grid structure with the first signal lines to reduce the voltage drop of the signal on the first signal lines. The first signal lines may include one or more of the first initial signal line, the second initial signal line, and the first power line. It should be noted that the light shielding layer located in the remaining display area AA4 may include both the second signal line and the second power line.

Some exemplary embodiments further provide a display device, which includes the above-mentioned display panel. The display device can be a display device such as a mobile phone, a tablet computer, a television, and the like.

Those skilled in the art will readily appreciate other embodiments of this disclosure after considering the specification and practicing what is disclosed herein. This application is intended to cover any variations, uses, or adaptations of this disclosure that follow the general principles of this disclosure and include common knowledge or customary technical means in the art that are not disclosed in this disclosure. The specification and embodiments are to be considered as exemplary only, and the true scope and spirit of this disclosure are indicated by the claims.

The drawings in this disclosure only relate to the structures involved in this disclosure, and other structures may refer to the usual design. In the absence of conflict, the embodiments of this disclosure and the features in the embodiments may be combined with each other to obtain new embodiments. It should be understood by those of ordinary skill in the art that the technical solutions of this disclosure may be modified or replaced by equivalents without departing from the spirit and scope of the technical solutions of this disclosure, and should fall within the scope of the claims of this disclosure.

It should be understood that this disclosure is not limited to the exact structures that have been described above and shown in the drawings, and that various modifications and changes may be made without departing from the scope thereof. The scope of this disclosure is limited only by the appended claims.

1. A display panel comprising a light emitting unit, further comprising:
a base substrate, comprising a light transmitting area;
a light shielding layer, located on a side of the base substrate and configured with a light shielding function;
a pixel defining layer, located on a side of the light shielding layer away from the base substrate, wherein a pixel opening is formed on the pixel defining layer, and the light emitting unit is formed in the pixel opening; and
multiple functional layers, located between the base substrate and the pixel defining layer, and orthographic projections, on the base substrate, of light shielding structures of the multiple functional layers are located outside the light transmitting area;
wherein a first opening is formed on the light shielding layer, and an orthographic projection of the first opening on the base substrate is located in the light transmitting area.

2. The display panel according to claim 1, further comprising a pixel driving circuit for driving the light emitting unit, wherein the pixel driving circuit comprises a driving transistor;
the multiple functional layers comprise:
a first active layer, comprising a third active part, wherein the third active part is configured to form a channel region of the driving transistor;
wherein the light shielding layer is located between the first active layer and the base substrate, the light shielding layer comprises a first light shielding part, and an orthographic projection of the first light shielding part on the base substrate covers an orthographic projection of the third active part on the base substrate.

3. The display panel according to claim 2, wherein the pixel driving circuit further comprises a first transistor and a fourth transistor, a first electrode of the first transistor is connected to a first initial signal line, a second electrode of the first transistor is connected to a gate of the driving transistor, a first electrode of the fourth transistor is connected to a data line, and a second electrode of the fourth transistor is connected to a first electrode of the driving transistor;
wherein the display panel further comprises:
a first reset signal line, wherein an orthographic projection of the first reset signal line on the base substrate extends along a first direction, and a partial structure of the first reset signal line is configured to form a top gate of the first transistor; and
a second gate line, wherein an orthographic projection of the second gate line on the base substrate extends along the first direction, and a partial structure of the second gate line is configured to form a gate of the fourth transistor;
wherein the orthographic projection of the first opening on the base substrate is located between the orthographic projections, on the base substrate, of the first reset signal line and the second gate line.

4. The display panel according to claim 2, comprising a plurality of repeating units, wherein the repeating units are arranged in an array in a first direction and a second direction, and the first direction intersects with the second direction;
wherein the repeating unit comprises two pixel driving circuits arranged in the first direction, and the two pixel driving circuits in the same repeating unit are arranged in mirror symmetry.

5. The display panel according to claim 4, wherein the pixel driving circuit further comprises a fourth transistor, a first electrode of the fourth transistor is connected to a data line, and a second electrode of the fourth transistor is connected to a first electrode of the driving transistor; and
wherein an orthographic projection of the data line on the base substrate extends along the second direction, and the orthographic projection of the first opening on the base substrate is located between orthographic projections, on the base substrate, of two adjacent data lines in the same repeating unit.

6. The display panel according to claim 2, wherein the pixel driving circuit further comprises a sixth transistor and a seventh transistor, a first electrode of the sixth transistor is connected to a second electrode of the driving transistor, a second electrode of the sixth transistor is connected to a first electrode of the light emitting unit, a first electrode of the seventh transistor is connected to a second initial signal line, and a second electrode of the seventh transistor is connected to the first electrode of the light emitting unit;
wherein the first active layer further comprises:
a sixth active part, configured to form a channel region of the sixth transistor;
a seventh active part, configured to form a channel region of the seventh transistor; and
an eighth active part, connected between the sixth active part and the seventh active part;
wherein the light shielding layer further comprises:
a second light shielding part, connected to the first light shielding part; and
wherein an orthographic projection of the eighth active part on the base substrate at least partially overlaps with an orthographic projection of the second light shielding part on the base substrate.

7. The display panel according to claim 6, wherein the orthographic projection of the eighth active part on the base substrate extends along a first direction, and a size, in the first direction, of the orthographic projection of the eighth active part on the base substrate is greater than a size, in a second direction, of the orthographic projection of the eighth active part on the base substrate; and
the orthographic projection of the second light shielding part on the base substrate extends along the first direction, and a size, in the first direction, of the orthographic projection of the second light shielding part on the base substrate is greater than a size, in the second direction, of the orthographic projection of the second light shielding part on the base substrate;
wherein the first direction intersects with the second direction.

8. The display panel according to claim 6, comprising a plurality of repeating units, wherein the repeating units are arranged in an array in a first direction and a second direction, and the first direction intersects with the second direction;
wherein the repeating unit comprises two pixel driving circuits arranged in the first direction, and the two pixel driving circuits in the same repeating unit are arranged in mirror symmetry; and
wherein the first light shielding layer further comprises:
a fourth light shielding part, provided corresponding to the repeating unit, wherein the fourth light shielding part is connected to two second light shielding parts in the corresponding repeating unit, the fourth light shielding part is connected to an end of the second light shielding part away from the first light shielding part, and the first opening is formed on the fourth light shielding part.

9. The display panel according to claim 6, wherein the pixel driving circuit further comprises a second transistor, a first electrode of the second transistor is connected to a gate of the driving transistor, and a second electrode of the second transistor is connected to the second electrode of the driving transistor;
the multiple functional layers further comprise:
a first conductive layer, located between the first active layer and the pixel defining layer, wherein the first conductive layer comprises a first conductive part, an orthographic projection of the first conductive part on the base substrate covers the orthographic projection of the third active part on the base substrate, and the first conductive part is configured to form the gate of the driving transistor; and
a fourth conductive layer, located between the first conductive layer and the pixel defining layer, wherein the fourth conductive layer comprises a first bridge part and a second bridge part;
wherein the first bridge part is connected to the first electrode of the second transistor, and the first bridge part is connected to the first conductive part through a via; the second bridge part is connected to the eighth active part through a via, and a size, in a first direction, of an orthographic projection of the second bridge part on the base substrate is greater than a size, in a second direction, of the orthographic projection of the second bridge part on the base substrate.

10. The display panel according to claim 2, wherein an area of the orthographic projection of the first opening on the base substrate is smaller than an area of the orthographic projection of the first light shielding part on the base substrate.

11. The display panel according to claim 2, wherein the pixel driving circuit further comprises a first transistor and a second transistor, a first electrode of the first transistor is connected to a first initial signal line, a second electrode of the first transistor is connected to a gate of the driving transistor, a first electrode of the second transistor is connected to the gate of the driving transistor, and a second electrode of the second transistor is connected to a second electrode of the driving transistor;
the multiple functional layers further comprise:
a first conductive layer, located between the first active layer and the pixel defining layer, wherein the first conductive layer comprises a first conductive part, an orthographic projection of the first conductive part on the base substrate covers the orthographic projection of the third active part on the base substrate, and the first conductive part is configured to form the gate of the driving transistor;
a fourth conductive layer, located between the first conductive layer and the pixel defining layer, wherein the fourth conductive layer comprises a first bridge part and the first initial signal line, and an orthographic projection of the first initial signal line on the base substrate extends along a first direction;
wherein the first bridge part is connected to the first electrode of the second transistor, and the first bridge part is connected to the first conductive part through a via.

12. The display panel according to claim 4, wherein the pixel driving circuit further comprises a capacitor, a first electrode of the capacitor is connected to a gate of the driving transistor, and a second electrode of the capacitor is connected to a first power line;
the multiple functional layers further comprise:
a first conductive layer, located between the first active layer and the pixel defining layer, wherein the first conductive layer comprises a first conductive part, an orthographic projection of the first conductive part on the base substrate covers the orthographic projection of the third active part on the base substrate, and the first conductive part is configured to form the gate of the driving transistor and the first electrode of the capacitor;
a second conductive layer, located between the first conductive layer and the pixel defining layer, wherein the second conductive layer comprises a second conductive part and a first connecting part, an orthographic projection of the second conductive part on the base substrate at least partially overlaps with the orthographic projection of the first conductive part on the base substrate, the second conductive part is configured to form the second electrode of the capacitor, and the first connecting part is connected between two second conductive parts in the same repeating unit;
a fourth conductive layer, located between the second conductive layer and the pixel defining layer, wherein the fourth conductive layer comprises a first power connection line, an orthographic projection of the first power connection line on the base substrate extends along the first direction, and the first power connection line is connected to the first connecting part through a via; and
a fifth conductive layer, located on a side of the fourth conductive layer away from the base substrate, wherein the fifth conductive layer comprises the first power line; and in two repeating units adjacent in the first direction, two adjacent first power lines are connected, and the two connected first power lines are connected to the first power connection line through a via.

13. The display panel according to claim 1, wherein the pixel defining layer is black, a second opening is further formed on the pixel defining layer, and an orthographic projection of the second opening on the base substrate is located in the light transmitting area; and
the orthographic projection of the second opening on the base substrate coincides with the orthographic projection of the first opening on the base substrate; or
an area of the orthographic projection of the second opening on the base substrate is greater than an area of the orthographic projection of the first opening on the base substrate, and the orthographic projection of the second opening on the base substrate covers the orthographic projection of the first opening on the base substrate; or
an area of the orthographic projection of the first opening on the base substrate is greater than an area of the orthographic projection of the second opening on the base substrate, and the orthographic projection of the first opening on the base substrate covers the orthographic projection of the second opening on the base substrate.

14. The display panel according to claim 2, comprising a display area, wherein the display area comprises an optical signal collection area, and the first opening is formed on at least the light shielding layer in the optical signal collection area.

15. The display panel according to claim 14, wherein the display area further comprises a normal display area outside the optical signal collection area; and
an orthographic projection, on the base substrate, of the light shielding layer located in the optical signal collection area and an orthographic projection, on the base substrate, of the light shielding layer located in the normal display area have different pattern shapes.

16. The display panel according to claim 14, wherein the display area further comprises a normal display area outside the optical signal collection area, and the first opening is further formed on the light shielding layer in the normal display area; and
an orthographic projection, on the base substrate, of the light shielding layer located in the optical signal collection area and an orthographic projection, on the base substrate, of the light shielding layer located in the normal display area have a same pattern shape.

17. The display panel according to claim 15, wherein the light shielding layer located in the optical signal collection area is provided as an entire surface except for the first opening.

18. The display panel according to claim 17, wherein the pixel driving circuit further comprises a plurality of switching transistors;
the first active layer further comprises:
a plurality of active parts, configured to form channel regions of the switch transistors;
wherein a plurality of first openings are further formed on the light shielding layer located in the optical signal collection area, the first openings are provided corresponding to the active parts, and orthographic projections of the first openings on the base substrate cover orthographic projections of corresponding active parts on the base substrate.

19-23. (canceled)

24. A display panel, comprising:
a base substrate;
a light shielding layer, located on a side of the base substrate and configured with a light shielding function; and
multiple functional layers, located on a side of the base substrate;
wherein a first opening is formed on the light shielding layer, an orthographic projection of the first opening on the base substrate does not overlap with orthographic projections, on the base substrate, of light shielding structures in the functional layers, and an orthographic projection of the light shielding layer on the base substrate overlaps with an orthographic projection, on the base substrate, of a light shielding structure in at least one of the functional layers.

25-26. (canceled)

27. A display device, comprising a display panel, wherein the display panel comprises:
a light emitting unit;
a base substrate, comprising a light transmitting area;
a light shielding layer, located on a side of the base substrate and configured with a light shielding function;
a pixel defining layer, located on a side of the light shielding layer away from the base substrate, wherein a pixel opening is formed on the pixel defining layer, and the light emitting unit is formed in the pixel opening; and
multiple functional layers, located between the base substrate and the pixel defining layer, and orthographic projections, on the base substrate, of light shielding structures of the multiple functional layers are located outside the light transmitting area;
wherein a first opening is formed on the light shielding layer, and an orthographic projection of the first opening on the base substrate is located in the light transmitting area.
